(19) United States
(12) Patent Application Publication
(10) Pub. No.: US 2021/0405529 A1
(43) Pub. Date: Dec. 30, 2021

(54) FILM FORMING MATERIAL FOR LITHOGRAPHY, COMPOSITION FOR FILM FORMATION FOR LITHOGRAPHY, UNDERLAYER FILM FOR LITHOGRAPHY, AND METHOD FOR FORMING PATTERN

(71) Applicant: Mitsubishi Gas Chemical Company, Inc., Tokyo (JP)

(72) Inventors: Junya HORIUCHI, Hiratsuka-shi, Kanagawa (JP); Takashi MAKINOSHIMA, Hiratsuka-shi, Kanagawa (JP); Masatoshi ECHIGO, Chiyoda-ku, Tokyo (JP)

(21) Appl. No.: 17/295,725

(22) PCT Filed: Nov. 21, 2019
(86) PCT No.: PCT/JP2019/045524

§ 371 Date: May 20, 2021

(30) Foreign Application Priority Data
Nov. 21, 2018 (JP) 2018-218081

(51) Int. Cl. G03F 7/039; G03F 7/11; C08G 73/12; C09D 179/08; H01L 21/027

(52) U.S. Cl. CPC G03F 7/039; G03F 7/11; H01L 21/0274; C09D 179/085; C08G 73/128

(57) ABSTRACT

The present invention has an object to provide a film forming material for lithography that is applicable to a wet process, has excellent heat resistance and film flatness in a supporting material having difference in level, and has excellent solubility in a solvent and long term storage stability in a solution form; and the like. The above object can be achieved by a film forming material for lithography comprising:
a compound having a group of formula (0A):

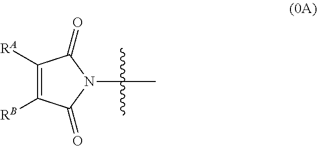

(In formula (0A),
R^{A} and R^{B} are each independently a hydrogen atom or an alkyl group having 1 to 4 carbon atoms); and
a latent curing accelerator.

### TECHNICAL FIELD

The present invention relates to a film forming material for lithography, a composition for film formation for lithography containing the material, an underlayer film for lithography formed by using the composition, and a method for forming a pattern (for example, a method for forming a resist pattern or a circuit pattern) by using the composition.

### BACKGROUND ART

In the production of semiconductor devices, fine processing is practiced by lithography using photoresist materials. In recent years, further miniaturization based on pattern rules has been demanded along with increase in the integration and speed of LSI. And now, lithography using light exposure, which is currently used as a general purpose technique, is approaching the limit of essential resolution derived from the wavelength of a light source.

The light source for lithography used upon forming resist patterns has been shifted to ArF excimer laser (193 nm) having a shorter wavelength from KrF excimer laser (248 nm). However, when the miniaturization of resist patterns proceeds, the problem of resolution or the problem of collapse of resist patterns after development arises. Therefore, resists have been desired to have a thinner film. Nevertheless, if resists merely have a thinner film, it is difficult to obtain the film thicknesses of resist patterns sufficient for supporting material processing. Therefore, there has been a need for a process of preparing a resist underlayer film between a resist and a semiconductor supporting material to be processed, and imparting functions as a mask for supporting material processing to this resist underlayer film in addition to a resist pattern.

Various resist underlayer films for such a process are currently known. For example, as a material for realizing resist underlayer films for lithography having the selectivity of a dry etching rate close to that of resists, unlike conventional resist underlayer films having a fast etching rate, an underlayer film forming material for a multilayer resist process containing a resin component having at least a substituent that generates a sulfonic acid residue by eliminating a terminal group under application of predetermined energy, and a solvent has been suggested (see Patent Literature 1). Moreover, as a material for realizing resist underlayer films for lithography having the selectivity of a dry etching rate smaller than that of resists, a resist underlayer film material comprising a polymer having a specific repeat unit has been suggested (see Patent Literature 2). Furthermore, as a material for realizing resist underlayer films for lithography having the selectivity of a dry etching rate smaller than that of semiconductor supporting materials, a resist underlayer film material comprising a polymer prepared by copolymerizing a repeat unit of an acenaphthylene and a repeat unit having a substituted or unsubstituted hydroxy group has been suggested (see Patent Literature 3).

Meanwhile, as materials having high etching resistance for this kind of resist underlayer film, amorphous carbon underlayer films formed by CVD using methane gas, ethane gas, acetylene gas, or the like as a raw material are well known.

In addition, the present inventors have suggested an underlayer film forming composition for lithography containing a naphthalene formaldehyde polymer comprising a particular structural unit and an organic solvent (see Patent Literatures 4 and 5) as a material that is not only excellent in optical properties and etching resistance, but also is soluble in a solvent and applicable to a wet process.

As for methods for forming an intermediate layer used in the formation of a resist underlayer film in a three-layer process, for example, a method for forming a silicon nitride film (see Patent Literature 6) and a CVD formation method for a silicon nitride film (see Patent Literature 7) are known. Also, as intermediate layer materials for a three-layer process, materials comprising a silsesquioxane-based silicon compound are known (see Patent Literatures 8 and 9).

### CITATION LIST

### Patent Literature

Patent Literature 1: Japanese Patent Application Laid-Open No. 2004-177668
Patent Literature 2: Japanese Patent Application Laid-Open No. 2004-271838
Patent Literature 3: Japanese Patent Application Laid-Open No. 2005-250434
Patent Literature 4: International Publication No. WO 2009/072465
Patent Literature 5: International Publication No. WO 2011/034062
Patent Literature 6: Japanese Patent Application Laid-Open No. 2002-334869
Patent Literature 7: International Publication No. WO 2004/066377
Patent Literature 8: Japanese Patent Application Laid-Open No. 2007-226170
Patent Literature 9: Japanese Patent Application Laid-Open No. 2007-226204

### SUMMARY OF INVENTION

### Technical Problem

As mentioned above, a large number of film forming materials for lithography have heretofore been suggested. However, none of these materials not only have high solvent solubility that permits application of a wet process such as spin coating or screen printing but also achieve both heat resistance and film flatness in a supporting material having difference in level at high dimensions. Thus, the development of novel materials is required.

The present invention has been made in light of the problems described above, and an object of the present invention is to provide a film forming material for lithography that is applicable to a wet process, has excellent heat resistance and film flatness in a supporting material having difference in level, and has excellent solubility in a solvent and long term storage stability in a solution form; a composition for film formation for lithography comprising the material; as well as a method for forming a photoresist layer, an underlayer film and a pattern for lithography by using the composition.

### Solution to Problem

The present inventors have, as a result of devoted examinations to solve the above problems, found out that use of a compound having a specific structure and a latent curing accelerator can solve the above problems, and reached the present invention. More specifically, the present invention is as follows.

[1]

A film forming material for lithography comprising: a compound having a group of formula (0A):

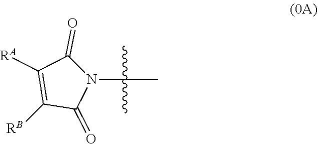

(In formula (0A),

R^{A} and R^{B} are each independently a hydrogen atom or an alkyl group having 1 to 4 carbon atoms); and

a latent curing accelerator.

[1-1]

The film forming material for lithography according to [1], wherein at least one of R^{A} and R^{B} is an alkyl group having 1 to 4 carbon atoms.

[2]

The film forming material for lithography according to [1] or [1-1], wherein the decomposition temperature of the latent curing accelerator is 600° C. or lower.

[3]

The film forming material for lithography according to [1] or [2], wherein the latent curing accelerator is a latent base generating agent.

[3-1]

The film forming material for lithography according to any one of [1] to [3], wherein the latent curing accelerator has a biguanide structure.

[4]

The film forming material for lithography according to any one of [1] to [3-1], wherein the compound having a group of formula (0A) has two or more groups of formula (0A).

[5]

The film forming material for lithography according to any one of [1] to [4], wherein the compound having a group of formula (0A) is a compound having two groups of formula (0A) or an addition polymerization resin of a compound having a group of formula (0A).

[6]

The film forming material for lithography according to any one of [1] to [5], wherein the compound having a group of formula (0A) is represented by formula (1A₀).

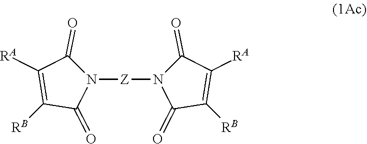

(In formula (1A₀),

R^{A} and R^{B} are as defined above; and

Z is a divalent hydrocarbon group having 1 to 100 carbon atoms and optionally containing a heteroatom.)

[7]

The film forming material for lithography according to any one of [1] to [6], wherein the compound having a group of formula (0A) is represented by formula (1A).

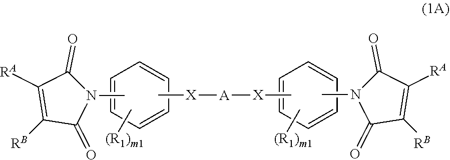

(In formula (1A),

R^{A} and R^{B} are as defined above;

each X is independently a single bond, —O—, —CH₂—, —C(CH₃)₂—, —CO—, —C(CF₃)₂—, —CONH—, or —COO—;

A is a single bond, an oxygen atom, or a divalent hydrocarbon group having 1 to 80 carbon atoms and optionally containing a heteroatom;

each R₁ is independently a group having 0 to 30 carbon atoms and optionally containing a heteroatom; and

each m1 is independently an integer of 0 to 4.)

[8]

The film forming material for lithography according to [7], wherein:

A is a single bond, an oxygen atom, —(CH₂)ₚ—, —CH₂C(CH₃)₂CH₂—, —(C(CH₃)₂)ₚ—, —(O(CH₂)_{q})ₚ—, — (O(C₆H₄))ₚ—, or any of the following structures:

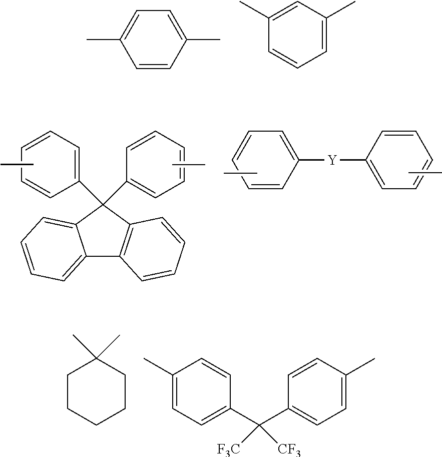

Y is a single bond, —O—, —CH₂—, —C(CH₃)₂—, —C(CF₃)₂—,

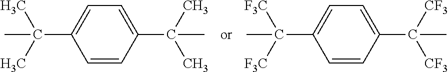

p is an integer of 0 to 20; and

q is an integer of 0 to 4. [8-1]

The film forming material for lithography according to [8], wherein:

X is —O—;

A is the following structure:

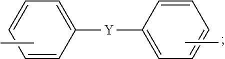

and

Y is —C(CH₃)₂—.

[9]

The film forming material for lithography according to any one of [1] to [5], wherein the compound having a group of formula (0A) is represented by formula (2A).

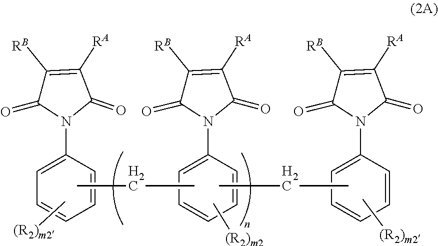

(In formula (2A),

R^{A} and R^{B} are as defined above;

each R₂ is independently a group having 0 to 10 carbon atoms and optionally containing a heteroatom;

each m2 is independently an integer of 0 to 3;

each m2′ is independently an integer of 0 to 4; and

n is an integer of 0 to 4.)

[9-1]

The film forming material for lithography according to [9], wherein n is an integer of 1 to 4.

[10]

The film forming material for lithography according to any one of [1] to [5], wherein the compound having a group of formula (0A) is represented by formula (3A).

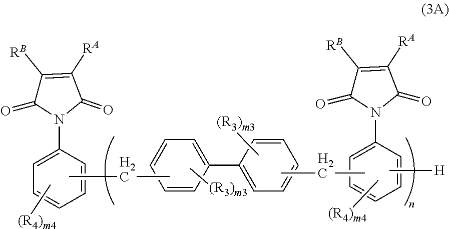

(In formula (3A),

R^{A} and R^{B} are as defined above;

R₃ and R₄ are each independently a group having 0 to 10 carbon atoms and optionally containing a heteroatom;

each m3 is independently an integer of 0 to 4;

each m4 is independently an integer of 0 to 4; and

n is an integer of 1 to 4.)

[10-1]

The film forming material for lithography according to [10], wherein n is an integer of 2 to 4.

[11]

The film forming material for lithography according to any one of [1] to [10-1], wherein a content ratio of the latent curing accelerator is 1 to 25 parts by mass based on 100 parts by mass of a total mass of the compound having a group of formula (0A).

[12]

The film forming material for lithography according to any one of [1] to [11], further comprising a crosslinking agent.

[13]

The film forming material for lithography according to [12], wherein the crosslinking agent is at least one selected from the group consisting of a phenol compound, an epoxy compound, a cyanate compound, an amino compound, a benzoxazine compound, a melamine compound, a guanamine compound, a glycoluril compound, a urea compound, an isocyanate compound, and an azide compound.

[14]

The film forming material for lithography according to [12] or [13], wherein the crosslinking agent has at least one allyl group.

[15]

The film forming material for lithography according to any one of [12] to [14], wherein a content ratio of the crosslinking agent is 0.1 to 100 parts by mass based on 100 parts by mass of a total mass of the compound having a group of formula (0A).

[16]

A composition for film formation for lithography comprising the film forming material for lithography according to any one of [1] to [15] and a solvent. The composition for film formation for lithography according to [16], wherein the film for lithography is an underlayer film for lithography.

[18]

An underlayer film for lithography formed by using the composition for film formation for lithography according to [17]. [19]

The composition for film formation for lithography according to [16], wherein the film for lithography is a resist film.

[20]

A resist film formed by using the composition for film formation for lithography according to [19]. [21]

A method for forming a resist pattern, comprising:

a resist film forming step of forming a resist film on a supporting material by using the composition for film formation for lithography according to [19]; and

a development step of irradiating a predetermined region of the resist film formed by the resist film forming step with radiation for development.

[22]

The method for forming a resist pattern according to [21], wherein the method is a method for forming an insulating film pattern.

A method for forming a resist pattern, comprising the steps of:

forming an underlayer film on a supporting material by using the composition for film formation for lithography according to [17];

forming at least one photoresist layer on the underlayer film; and

irradiating a predetermined region of the photoresist layer with radiation for development.

[24]

A method for forming a circuit pattern, comprising the steps of:

forming an underlayer film on a supporting material by using the composition for film formation for lithography according to [17];

forming an intermediate layer film on the underlayer film by using a resist intermediate layer film material containing a silicon atom;

forming at least one photoresist layer on the intermediate layer film;

irradiating a predetermined region of the photoresist layer with radiation for development, thereby forming a resist pattern;

etching the intermediate layer film with the resist pattern as a mask;

etching the underlayer film with the obtained intermediate layer film pattern as an etching mask; and etching the supporting material with the obtained underlayer film pattern as an etching mask, thereby forming a pattern on the supporting material.

### Advantageous Effects of Invention

The present invention can provide a film forming material for lithography that is applicable to a wet process, and is useful for forming a photoresist underlayer film that is not only excellent in heat resistance and film flatness in a supporting material having difference in level, but also has solubility in a solvent, long term storage stability in a solution form, and curability at low temperature; a composition for film formation for lithography comprising the material; as well as an underlayer film for lithography and a method for forming a pattern by using the composition.

### DESCRIPTION OF EMBODIMENTS

Hereinafter, embodiments of the present invention will be described. The embodiments described below are given merely for illustrating the present invention. The present invention is not limited only by these embodiments.

### [Film Forming Material for Lithography]

### <Compound>

One embodiment of the present invention relates to a film forming material for lithography comprising:

a compound having a group of formula (0A):

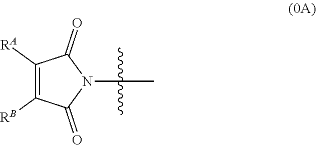

(In formula (0A),

R^{A} and R^{B} are each independently a hydrogen atom or an alkyl group having 1 to 4 carbon atoms.); and

a latent curing accelerator. At least one of R^{A} and R^{B} may be an alkyl group having 1 to 4 carbon atoms.

It is preferable that the compound having a group of formula (0A) (hereinafter, referred to as a “compound 0A”) have two or more groups of formula (0A). The compound 0A can be obtained by conducting a ring closure reaction with dehydration between, for example, a compound having one or more primary amino groups in the molecule and maleic anhydride or citraconic anhydride.

From the viewpoint of heat resistance and film flatness in a supporting material having difference in level, the total content of the compound 0A in the film forming material for lithography of the present embodiment is preferably 51 to 98% by mass, more preferably 60 to 96% by mass, still more preferably 70 to 94% by mass, and particularly preferably 80 to 92% by mass.

The compound 0A in the film forming material for lithography of the present embodiment is characterized by having a function other than those as an acid generating agent or base generating agent for film formation for lithography.

For the compound 0A to be used in the film forming material for lithography of the present embodiment, a compound having two groups of formula (0A) and a resin formed by addition-polymerizing a compound having a group of formula (0A) are preferable from the viewpoint of the availability of raw materials and production enabling mass production.

The compound 0A is preferably a compound represented by formula (1A₀):

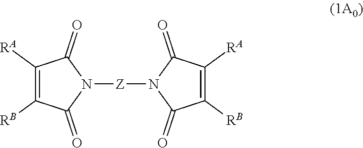

(In formula (1A₀),

R^{A} and R^{B} are as defined above; and

Z is a divalent hydrocarbon group having 1 to 100 carbon atoms and optionally containing a heteroatom.)

The number of carbon atoms in the hydrocarbon group may be 1 to 80, 1 to 60, 1 to 40, 1 to 20, or the like. Examples of the heteroatom may include oxygen, nitrogen, sulfur, fluorine, silicon.

The compound 0A is preferably a compound represented by formula (1A):

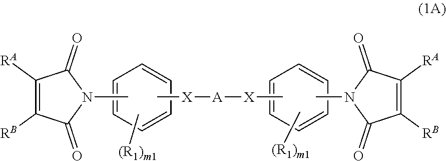

(In formula (1A),

R^{A} and R^{B} are as defined above;

each X is independently a single bond, —O—, —CH₂—, —C(CH₃)₂—, —CO—, —C(CF₃)₂—, —CONH—, or —COO—;

A is a single bond, an oxygen atom, or a divalent hydrocarbon group having 1 to 80 carbon atoms and optionally containing a heteroatom (for example, oxygen, nitrogen, sulfur, fluorine);

each R₁ is independently a group having 0 to 30 carbon atoms and optionally containing a heteroatom (for example, oxygen, nitrogen, sulfur, fluorine, chlorine, bromine, iodine); and

each m1 is independently an integer of 0 to 4.)

From the viewpoint of improvement in heat resistance and etching resistance, in formula (1A), it is preferable that A be a single bond, an oxygen atom, —(CH₂)ₚ—, —CH₂C(CH₃)₂CH₂—, —(C(CH₃)₂)ₚ—, —(O(CH₂)_{q})ₚ—, —(O(C₆H₄))ₚ—, or any of the following structures:

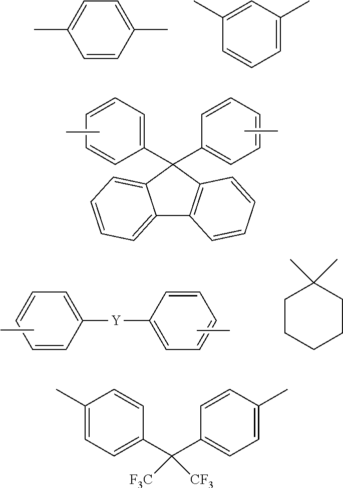

it is preferable that Y be a single bond, —O—, —CH₂—, —C(CH₃)₂—, —C(CF₃)₂—,

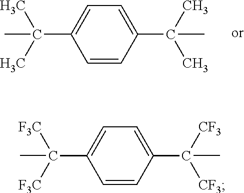

it is preferable that p be an integer of 0 to 20; and

it is preferable that q be an integer of 0 to 4.

X is preferably a single bond from the viewpoint of heat resistance, and is preferably —COO— from the viewpoint of solubility.

Y is preferably a single bond from the viewpoint of improvement in heat resistance.

R₁ is preferably a group having 0 to 20 or 0 to 10 carbon atoms and optionally containing a heteroatom (for example, oxygen, nitrogen, sulfur, fluorine, chlorine, bromine, iodine). R₁ is preferably a hydrocarbon group from the viewpoint of improvement in solubility in an organic solvent. For example, examples of R₁ include an alkyl group (for example, an alkyl group having 1 to 6 or 1 to 3 carbon atoms), and specific examples include a methyl group, an ethyl group.

m1 is preferably an integer of 0 to 2, and is more preferably 1 or 2 from the viewpoint of the availability of raw materials and improved solubility.

q is preferably an integer of 2 to 4.

p is preferably an integer of 0 to 2, and is more preferably an integer of 1 to 2 from the viewpoint of improvement in heat resistance.

As an example, in formula (1A),

R^{A} and R^{B} are each independently a hydrogen atom or an alkyl group having 1 to 4 carbon atoms (at least one of R^{A} and R^{B} may be an alkyl group having 1 to 4 carbon atoms);

X is —O—;

A is the following structure:

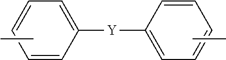

Y is —C(CH₃)₂—;

each R₁ is independently a group having 0 to 30 carbon atoms and optionally containing a heteroatom; and

each m1 is independently an integer of 0 to 4.

### <Addition Polymerization Resin>

From the viewpoint of improvement in the heat resistance, embedding properties and flatness of the cured film, it is preferable that the compound 0A be a compound represented by formula (2A).

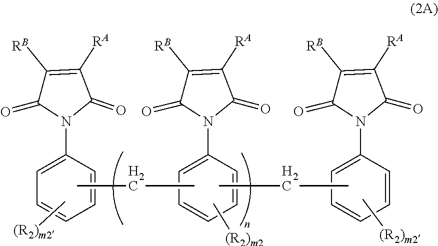

(In formula (2A),

R^{A} and R^{B} are as defined above;

each R₂ is independently a group having 0 to 10 carbon atoms and optionally containing a heteroatom;

each m2 is independently an integer of 0 to 3;

each m2′ is independently an integer of 0 to 4; and

n is an integer of 0 to 4.)

In the above formula (2A) and formula (2B), each R₂ is independently a group having 0 to 10 carbon atoms and optionally containing a heteroatom (for example, oxygen, nitrogen, sulfur, fluorine, chlorine, bromine, iodine). In addition, R₂ is preferably a hydrocarbon group from the viewpoint of improvement in solubility in an organic solvent. For example, examples of R₂ include an alkyl group (for example, an alkyl group having 1 to 6 or 1 to 3 carbon atoms), and specific examples include a methyl group, an ethyl group.

Each m2 is independently an integer of 0 to 3. In addition, m2 is preferably 0 or 1, and is more preferably 0 from the viewpoint of the availability of raw materials.

Each m2′ is independently an integer of 0 to 4. In addition, m2′ is preferably 0 or 1, and is more preferably 0 from the viewpoint of the availability of raw materials.

n is an integer of 0 to 4. In addition, n is preferably an integer of 1 to 4, and is more preferably an integer of 1 to 2 from the viewpoint of improvement in heat resistance. When n is 1 or more, the monomers that can be responsible for the sublimate are removed, and both flatness and heat resistance can be expected. It is more preferable that n be 1.

From the viewpoint of improvement in the heat resistance and film flatness in a supporting material having difference in level of the cured film, it is preferable that the compound 0A be a compound represented by formula (3A).

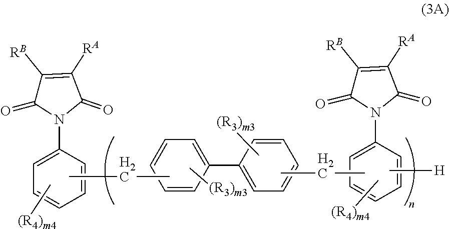

(In formula (3A),

R^{A} and R^{B} are as defined above;

R₃ and R₄ are each independently a group having 0 to 10 carbon atoms and optionally containing a heteroatom;

each m3 is independently an integer of 0 to 4;

each m4 is independently an integer of 0 to 4; and

n is an integer of 1 to 4)

In the above formula (3A), R₃ and R₄ are each independently a group having 0 to 10 carbon atoms and optionally containing a heteroatom (for example, oxygen, nitrogen, sulfur, fluorine, chlorine, bromine, iodine). In addition, R₃ and R₄ are preferably hydrocarbon groups from the viewpoint of improvement in solubility in an organic solvent. For example, examples of R₃ and R₄ include an alkyl group (for example, an alkyl group having 1 to 6 or 1 to 3 carbon atoms), and specific examples include a methyl group, an ethyl group.

Each m3 is independently an integer of 0 to 4. In addition, m3 is preferably an integer of 0 to 2, and is more preferably 0 from the viewpoint of the availability of raw materials.

Each m4 is independently an integer of 0 to 4. In addition, m4 is preferably an integer of 0 to 2, and is more preferably 0 from the viewpoint of the availability of raw materials.

n is an integer of 1 to 4. In addition, n is preferably an integer of 2 to 4, and from the viewpoint of improvement in heat resistance, is more preferably an integer of 2 to 3, and still more preferably 2. When n is 2 or more, the monomers that can be responsible for the sublimate are removed, and both flatness and heat resistance can be expected. It is more preferable that n be 2.

Specific examples of the compound 0A used in the present embodiment include bismaleimides and biscitraconimides obtained from bisamines containing a phenylene skeleton such as m-phenylenediamine, 4-methyl-1.3-phenylenediamine, 4,4-diaminodiphenylmethane, 4,4-diaminodiphenyl sulfone, 1,3-bis(3-aminophenoxy)benzene, 1.3-bis(4-aminophenoxy)benzene, 1,4-bis(3-aminophenoxy)benzene and 1,4-bis(4-aminophenoxy)benzene; bismaleimides and biscitraconimides obtained from bisamines containing a diphenylalkane skeleton such as bis(3-ethyl-5-methyl-4-aminophenyl)methane, 1,1-bis(3-ethyl-5-methyl-4-aminophenyl)ethane, 2,2-bis(3-ethyl-5-methyl-4-aminophenyl)propane, N,N′-4,4′-diamino-3,3′-dimethyldiphenylmethane, N,N′-4,4′-diamino-3,3′-dimethyl-1,1-diphenylethane, N,N′-4,4′-diamino-3,3′-dimethyl-1,1-diphenylpropane, N,N′-4,4′-diamino-3,3′-diethyldiphenylmethane, N,N′-4,4′-diamino-3,3′-di-n-propyldiphenylmethane and N,N′-4,4′-diamino-3,3′-di-n-butyldiphenylmethane; bismaleimides and biscitraconimides obtained from bisamines containing a biphenyl skeleton such as N,N′-4,4′-diamino-3,3′-dimethyl-biphenylene and N,N′-4,4′-diamino-3,3′-diethyl-biphenylene; bismaleimides and biscitraconimides obtained from bisamines containing an aliphatic skeleton such as 1,6-hexanediamine, 1,6-bisamino-(2,2,4-trimethyl)hexane, 1,3-dimethylenecyclohexanediamine and 1,4-dimethylenecyclohexanediamine; bismaleimides and biscitraconimides obtained from diamino siloxane such as 1.3-bis(3-aminopropyl)-1,1,2,2-tetramethyl disiloxane, 1.3-bis(3-aminobutyl)-1,1,2,2-tetramethyl disiloxane, bis(4-aminophenoxy)dimethyl silane, 1,3-bis(4-aminophenoxy)tetramethyl disiloxane, 1,1,3,3-tetramethyl-1.3-bis(4-aminophenyl)disiloxane, 1,1,3,3-tetraphenoxy-1.3-bis(2-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(4-aminobutyl)disiloxane, 1,3-dimethyl-1,3-dimethoxy-1.3-bis(4-aminobutyl)disiloxane, 1,1,3,3,5,5-hexamethyl-1.5-bis(4-aminophenyl)trisiloxane, 1,1,5,5-tetraphenyl-3.3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane and 1,1,3,3,5,5-hexapropyl-1.5-bis(3-aminopropyl)trisiloxane; and the like.

Among the bismaleimide compounds described above, bis(3-ethyl-5-methyl-4-maleimidephenyl)methane, N,N′-4,4′-[3,3′-dimethyl-diphenylmethane]bismaleimide, and N,N′-4,4′-[3,3′-diethyldiphenylmethane]bismaleimide are particularly preferable because they are excellent in curability, as well as heat resistance.

Among the biscitraconimide compounds described above, bis(3-ethyl-5-methyl-4-citraconimidephenyl)methane, N,N′-4,4′-[3,3′-dimethyl-diphenylmethane]biscitraconimide, and N,N′-4,4′-[3,3′-diethyldiphenylmethane]biscitraconimide are particularly preferable because they are excellent in solvent solubility.

Examples of the addition polymerization maleimide resin to be used in the present embodiment include, for example, Bismaleimide M-20 (manufactured by Mitsui Chemicals, Inc., trade name), BMI-2300 (manufactured by Daiwa Kasei Industry Co., Ltd., trade name), BMI-3200 (manufactured by Daiwa Kasei Industry Co., Ltd., trade name), MIR-3000 (manufactured by Nippon Kayaku Co., Ltd., product name). Among them, BMI-2300 is particularly preferable because it is excellent is solubility, as well as heat resistance.

### <Latent Curing Accelerator>

The film forming material for lithography of the present embodiment contains a latent curing accelerator for accelerating crosslinking and curing reaction. A latent curing accelerator is a curing accelerator that does not exhibit activity under normal storage conditions, but exhibits activity in response to an external stimulus (for example, heat, light, and the like). By using a latent curing accelerator, long term stable storage is possible under normal room temperature storage conditions regardless of the season.

From the viewpoint of controlling the cure rate and controlling the flatness of the cured film, the decomposition temperature of the latent curing accelerator is, for example, 600° C. or lower, preferably 450° C. or lower, more preferably 400° C. or lower, still more preferably 350° C. or lower, and most preferably 240° C. or lower. The “decomposition temperature” means a temperature at which a latent curing accelerator is decomposed to produce a substance having a curing accelerating effect.

The lower limit of the decomposition temperature is, for example, 100° C., more preferably 150° C., still more preferably 200° C., and most preferably 220° C.

Due to the structural characteristics of the compound that can be used in the embodiments of the present invention, a latent base generating agent is preferable as the latent curing accelerator. Examples of the latent base generating agent include those that generate a base by thermal decomposition (thermal latent base generating agent) and those that generate a base by light irradiation (photo-latent base generating agent). The photo-latent base generating agent can also generate a base by thermal decomposition.

Examples of the thermal latent base generating agent include an acidic compound (A1) that generates a base when heated to 40° C. or higher, and an ammonium salt (A2) having an anion having a pKal of 0 to 4 and an ammonium cation.

Since the acidic compound (A1) and the ammonium salt (A2) generate bases when heated, the bases generated from these compounds can accelerate the crosslinking and curing reactions. Moreover, since the cyclization of the film forming material for lithography hardly progresses unless these compounds are heated, a film forming composition for lithography having excellent stability can be prepared.

Examples of the photo-latent base generating agent include a neutral compound that generates a base when exposed to electromagnetic waves. Examples of those that generate amines include benzyl carbamates, benzoin carbamates, O-carbamoyl hydroxyamines, O-carbamoyl oximes, and RR′—N—CO—OR″ (wherein R and R′ are a hydrogen or a lower alkyl, and R″ is a nitrobenzyl or an α-methyl-nitrobenzyl). In particular, in order to obtain storage stability upon adding to a solution and suppress volatilization during baking due to low vapor pressure, a borate compound that generates a tertiary amine, a quaternary ammonium salt containing dithiocarbamate as an anion (C. E. Hoyle, et. al., Macromolecules, 32, 2793 (1999)), or the like is preferable.

Specific examples of the latent base generating agent used in the present embodiment include the following.

### (Examples of Hexaammineruthenium (III) Triphenylalkylborates)

Hexaammineruthenium (III)
tris(triphenylmethylborate), hexaammineruthenium (III)
tris(triphenylethylborate), hexaammineruthenium (III)
tris(triphenylpropylborate), hexaammineruthenium (III)
tris(triphenylbutylborate), hexaammineruthenium (III)
tris(triphenylhexylborate), hexaammineruthenium (III)
tris(triphenyloctylborate), hexaammineruthenium (III)
tris(triphenyloctadecylborate), hexaammineruthenium (III)
tris(triphenylisopropylborate), hexaammineruthenium (III)
tris(triphenylisobutylborate), hexaammineruthenium (III)
tris(triphenyl-sec-butylborate), hexaammineruthenium (III) tris(triphenyl-tert-butylborate),
hexaammineruthenium (III) tris(triphenylneopentylborate), and the like.

### (Examples of Hexaammineruthenium (III) Triphenylborates)

Hexaammineruthenium (III)
tris(triphenylcyclopenthylborate), hexaammineruthenium (III) tris(triphenylcyclohexylborate),
hexaammineruthenium (III) tris[triphenyl(4-decylcyclohexyl)borate], hexaammineruthenium (III) tris[triphenyl(fluoromethyl)borate], hexaammineruthenium (III) tris[triphenyl(chloromethyl)borate],
hexaammineruthenium (III) tris[triphenyl(bromomethyl)borate], hexaammineruthenium (III) tris[triphenyl(trifluoromethyl)borate],
hexaammineruthenium (III) tris[triphenyl(trichloromethyl)borate],
hexaammineruthenium (III) tris[triphenyl(hydroxymethyl)borate], hexaammineruthenium (III) tris[triphenyl(carboxymethyl)borate],
hexaammineruthenium (III) tris[triphenyl(cyanomethyl)borate], hexaammineruthenium (III) tris[triphenyl(nitromethyl)borate]),
hexaammineruthenium (III) tris[triphenyl(azidomethyl)borate], and the like.

### (Examples of Hexaammineruthenium (III) Triarylbutylborates)

Hexammineruthenium (III) tris[tris(1-naphthyl)butylborate], hexaammineruthenium (III) tris[tris(2-naphthyl)butylborate], hexaammineruthenium (III) tris[tris(o-tolyl)butylborate], hexaammineruthenium (III) tris[tris(m-tolyl)butylborate], hexaammineruthenium (III) tris[tris(p-tolyl)butylborate], hexammineruthenium (III) tris[tris(2,3-xylyl)butylborate],
hexaammineruthenium (III) tris[tris(2,5-xylyl)butylborate], and the like.

### (Examples of Ruthenium (III) Tris(Triphenylbutylborates))

Tris(ethylenediamine)ruthenium (III)
tris(triphenylbutylborate), cis-diamminebis(ethylenediamine)ruthenium (III) tris(triphenylbutylborate), trans-diamminebis(ethylenediamine)ruthenium (III) tris(triphenylbutylborate),
tris(trimethylenediamine)ruthenium (III) tris(triphenylbutylborate),
tris(propylenediamine)ruthenium (III) tris(triphenylbutylborate), tetraammine{(−)(propylenediamine)}ruthenium (III) tris(triphenylbutylborate), tris(trans-1,2-cyclohexanediamine)ruthenium (III) tris(triphenylbutylborate),
bis(diethylenetriamine)ruthenium (III) tris(triphenylbutylborate),
bis(pyridine)bis(ethylenediamine)ruthenium (III) tris(triphenylbutylborate),
bis(imidazole)bis(ethylenediamine)ruthenium (III) tris(triphenylbutylborate), and the like.

The latent base generating agent can be easily produced by mixing a halogen salt, sulfate salt, nitrate salt, acetate salt or the like of each complex ion with an alkali metal borate salt in an appropriate solvent such as water, alcohol or a hydrous organic solvent. The halogen salts, sulfate salts, nitrate salts, acetate salts, and the like of each complex ion used as raw materials are easily available as commercial products, and their synthesis method is described, for example, in Nihonkagakukai-hen, shin jikken kagaku kōza 8 (muki kagōbutsu no gōsei III), Maruzen (1977) (New Experimental Chemistry Course 8 (Synthesis of Inorganic Compounds III), edited by The Chemical Society of Japan, Maruzen (1977)), and the like.

In addition, examples of the photo-latent base generating agent include those having a biguanide structure, specifically 1,2-dicyclohexyl-4,4,5,5-tetramethylbiguanidium n-butyltriphenylborate (trade name: WPBG-300, manufactured by FUJIFILM Wako Pure Chemical Corporation), and 1,2-diisopropyl-3-[bis(dimethylamino)methylene]guanidium 2-(3-benzoylphenyl)propionate (trade name: WPBG-266, manufactured by FUJIFILM Wako Pure Chemical Corporation).

The content of the latent curing accelerator may be any amount as long as it is a stoichiometrically required amount relative to the mass of the compound 0A, but it is preferably 1 to 25 parts by mass and more preferably 1 to 15 parts by mass, based on 100 parts by mass of the mass of the compound 0A. When the content of the latent curing accelerator is 1 part by mass or more, there is a tendency that curing of the film forming material for lithography can be prevented from being insufficient. On the other hand, when the content of the latent curing accelerator is 25 parts by mass or less, there is a tendency that the long term storage stability of the film forming material for lithography at room temperature can be prevented from being impaired.

The film forming material for lithography of the present embodiment is applicable to a wet process. In addition, a preferred film forming material for lithography of the present embodiment has an aromatic structure and also has a rigid skeleton, and therefore, when it is baked at a high temperature, its functional group undergoes a crosslinking reaction even on its own, thereby expressing high heat resistance. As a result, deterioration of the film upon baking at a high temperature is suppressed and an underlayer film excellent in etching resistance to plasma etching and the like can be formed. Furthermore, even though the preferred film forming material for lithography of the present embodiment has an aromatic structure, its solubility in an organic solvent is high and its solubility in a safe solvent is high. In addition, by containing a latent base generating agent for accelerating the crosslinking and curing reactions, it is excellent in long term storage stability under normal room temperature storage conditions regardless of the season, and it is also excellent from the viewpoint of process control since the film formation is possible at a predetermined temperature or higher or under predetermined light irradiation conditions. Furthermore, an underlayer film for lithography composed of the composition for film formation for lithography of the present embodiment, which will be mentioned later, is not only excellent in film flatness in a supporting material having difference in level, thereby having a good stability of the product quality, but also excellent in adhesiveness to a resist layer or a resist intermediate layer film material, and thus, an excellent resist pattern can be obtained.

### <Crosslinking Agent>

The film forming material for lithography of the present embodiment may comprise a crosslinking agent, if required, from the viewpoint of lowering the curing temperature, suppressing intermixing, and the like.

The crosslinking agent is not particularly limited as long as it undergoes a crosslinking reaction with the compound 0A, and any of known crosslinking systems can be applied, but specific examples of the crosslinking agent that may be used in the present embodiment include, but are not particularly limited to, phenol compounds, epoxy compounds, cyanate compounds, amino compounds, benzoxazine compounds, acrylate compounds, melamine compounds, guanamine compounds, glycoluril compounds, urea compounds, isocyanate compounds, azide compounds and the like. These crosslinking agents can be used alone as one kind, or can be used in combination of two or more kinds. Among them, a benzoxazine compound, an epoxy compound, or a cyanate compound is preferable, and a benzoxazine compound is more preferable from the viewpoint of improvement in etching resistance.

In a crosslinking reaction between the compound 0A and the crosslinking agent, for example, an active group these crosslinking agents have (a phenolic hydroxy group, an epoxy group, a cyanate group, an amino group, or a phenolic hydroxy group formed by ring opening of the alicyclic site of benzoxazine) undergoes an addition reaction with a carbon-carbon double bond of the compound 0A to form crosslinkage. Besides, two carbon-carbon double bonds of the compound 0A are polymerized to form crosslinkage.

As the above phenol compound, a publicly known compound can be used. For example, examples thereof include those described in International Publication No. WO 2018-016614. Preferably, an aralkyl-based phenol resin is desirable from the viewpoint of heat resistance and solubility.

As the above epoxy compound, a publicly known compound can be used and is selected from among compounds having two or more epoxy groups in one molecule. For example, examples thereof include those described in International Publication No. WO 2018/016614. These epoxy resins may be used alone, or may be used in combination of two or more kinds. An epoxy resin that is in a solid state at normal temperature, such as an epoxy resin obtained from a phenol aralkyl resin or a biphenyl aralkyl resin is preferable from the viewpoint of heat resistance and solubility.

The above cyanate compound is not particularly limited as long as the compound has two or more cyanate groups in one molecule, and a publicly known compound can be used. For example, examples thereof include those described in International Publication No. WO 2011-108524, but preferable examples of the cyanate compound in the present embodiment include cyanate compounds having a structure where hydroxy groups of a compound having two or more hydroxy groups in one molecule are substituted with cyanate groups. Also, the cyanate compound preferably has an aromatic group, and those having a structure in which a cyanate group is directly bonded to the aromatic group can be suitably used. Examples of such a cyanate compound include those described in International Publication No. WO 2018-016614. These cyanate compounds may be used alone, or may be used in arbitrary combination of two or more kinds. Also, the above cyanate compound may be in any form of a monomer, an oligomer, and a resin.

Examples of the above amino compound include those described in International Publication No. WO 2018-016614.

The structure of oxazine of the above benzoxazine compound is not particularly limited, and examples thereof include a structure of oxazine having an aromatic group including a condensed polycyclic aromatic group, such as benzoxazine and naphthoxazine.

Examples of the benzoxazine compound include, for example, compounds represented by the following general formulas (a) to (f). Note that, in the general formulas described below, a bond displayed toward the center of a ring indicates a bond to any carbon that constitutes the ring and to which a substituent can be bonded.

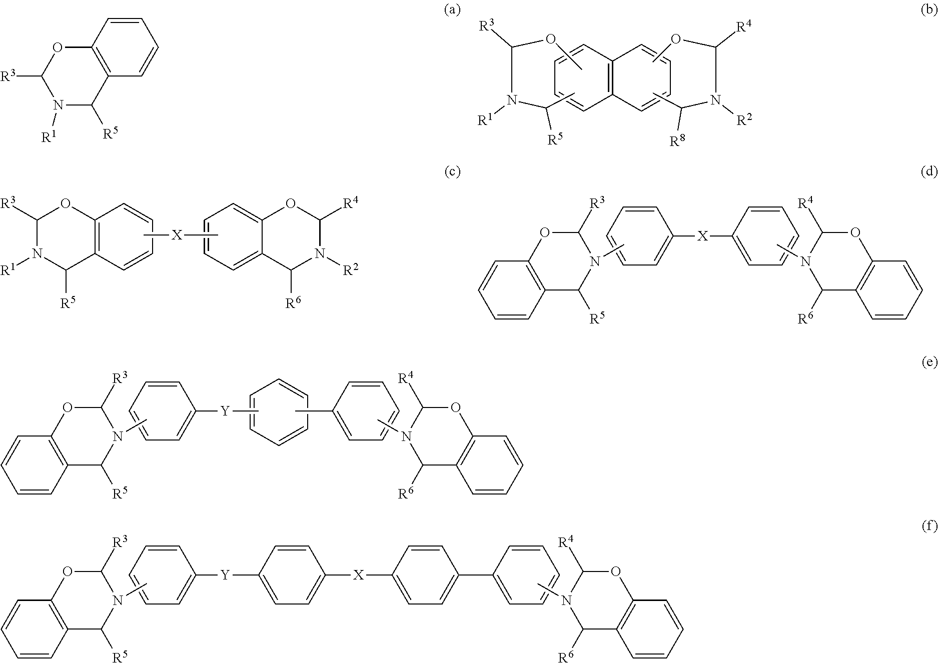

In the general formulas (a) to (c), R1 and R2 independently represent an organic group having 1 to 30 carbon atoms. In addition, in the general formulas (a) to (f), R3 to R6 independently represent hydrogen or a hydrocarbon group having 1 to 6 carbon atoms. Moreover, in the above general formulas (c), (d), and (f), X independently represents a single bond, —O—, —S—, —S—S—, —SO₂—, —CO—, —CONH—, —NHCO—, —C(CH₃)₂—, —C(CF₃)₂—, —(CH₂)m-, —O—(CH₂) m-O—, or —S—(CH₂) m-S—. Here, m is an integer of 1 to 6. In addition, in the general formulas (e) and (f), Y independently represents a single bond, —O—, —S—, —CO—, —C(CH₃)₂—, —C(CF₃)₂—, or alkylene having 1 to 3 carbon atoms.

Moreover, the benzoxazine compound includes an oligomer or polymer having an oxazine structure as a side chain, and an oligomer or polymer having a benzoxazine structure in the main chain.

The benzoxazine compound can be produced in a similar method as a method described in International Publication No. WO 2004/009708, Japanese Patent Application Laid-Open No. 11-12258, or Japanese Patent Application Laid-Open No. 2004-352670.

Examples of the above melamine compound include those described in International Publication No. WO 2018-016614.

Examples of the above guanamine compound include those described in International Publication No. WO 2018-016614.

Examples of the above glycoluril compound include those described in International Publication No. WO 2018-016614.

Examples of the above urea compound include those described in International Publication No. WO 2018-016614.

In the present embodiment, a crosslinking agent having at least one allyl group may be used from the viewpoint of improvement in crosslinkability. Specific examples of the crosslinking agent having at least one allyl group include, but are not limited to, those described in International Publication No. WO 2018-016614. These crosslinking agents having at least one allyl group may be alone, or may be a mixture of two or more kinds. Among them, an allylphenol such as 2,2-bis(3-allyl-4-hydroxyphenyl)propane, 1,1,1,3,3,3-hexafluoro-2,2-bis(3-allyl-4-hydroxyphenyl)propane, bis(3-allyl-4-hydroxyphenyl)sulfone, bis(3-allyl-4-hydroxyphenyl)sulfide, and bis(3-allyl-4-hydroxyphenyl) ether is preferable from the viewpoint of excellent compatibility with the compound 0A.

The film for lithography of the present embodiment can be formed by crosslinking and curing the film forming material for lithography of the present embodiment alone, or after compounding with the above crosslinking agent, by a publicly known method. Examples of the crosslinking method include approaches such as heat curing and light curing.

The content ratio of the crosslinking agent is in the range of 0.1 to 100 parts by mass based on 100 parts by mass of the total mass of the compound 0A, preferably in the range of 1 to 50 parts by mass from the viewpoint of heat resistance and solubility, and more preferably in the range of 1 to 30 parts by mass.

### <Radical Polymerization Initiator>

The film forming material for lithography of the present embodiment can contain, if required, a radical polymerization initiator. The radical polymerization initiator may be a photopolymerization initiator that initiates radical polymerization by light, or may be a thermal polymerization initiator that initiates radical polymerization by heat.

Examples of such a radical polymerization initiator include those described in International Publication No. WO 2018-016614. As the radical polymerization initiator according to the present embodiment, one kind thereof may be used alone, or two or more kinds thereof may be used in combination.

The content of the above radical polymerization initiator may be any amount as long as it is a stoichiometrically required amount relative to the total mass of the compound 0A, but it is preferably 0.01 to 25 parts by mass and more preferably 0.01 to 10 parts by mass, based on 100 parts by mass of the total mass of the compound 0A. When the content of the radical polymerization initiator is 0.01 parts by mass or more, there is a tendency that curing can be prevented from being insufficient. On the other hand, when the content of the radical polymerization initiator is 25 parts by mass or less, there is a tendency that the long term storage stability of the film forming material for lithography at room temperature can be prevented from being impaired.

### [Resist Composition]

The resist composition of the present embodiment includes the film forming material for lithography in the present embodiment described above.

It is preferable that the resist composition of the present embodiment further contains a solvent. The solvent is not particularly limited, and examples thereof include a solvent described in International Publication No. WO 2013/024778. These solvents can be used alone or in combination of two or more kinds.

The solvent is preferably a safe solvent, more preferably at least one selected from PGMEA (propylene glycol monomethyl ether acetate), PGME (propylene glycol monomethyl ether), CHN (cyclohexanone), CPN (cyclopentanone), ortho-xylene (OX), 2-heptanone, anisole, butyl acetate, ethyl propionate, and ethyl lactate.

In the present embodiment, the amount of the solid components and the amount of the solvent are not particularly limited, but preferably the solid components are 1 to 80% by mass and the solvent is 20 to 99% by mass, more preferably the solid components are 1 to 50% by mass and the solvent is 50 to 99% by mass, still more preferably the solid components are 2 to 40% by mass and the solvent is 60 to 98% by mass, and particularly preferably the solid components are 2 to 10% by mass and the solvent is 90 to 98% by mass, based on 100% by mass of the total mass of the amount of the solid components and the solvent.

### [Composition for Film Formation for Lithography]

A composition for film formation for lithography of the present embodiment comprises the above film forming material for lithography and a solvent. The film for lithography is, for example, an underlayer film for lithography.

The composition for film formation for lithography of the present embodiment can form a desired cured film by applying it on a base material, subsequently heating it to evaporate the solvent if necessary, and then heating or photoirradiating it. A method for applying the composition for film formation for lithography of the present embodiment is arbitrary, and a method such as spin coating, dipping, flow coating, inkjet coating, spraying, bar coating, gravure coating, slit coating, roll coating, transfer printing, brush coating, blade coating, and air knife coating can be employed appropriately.

The temperature at which the film is heated is not particularly limited according to the purpose of evaporating the solvent, and the heating can be carried out at, for example, 40 to 400° C. A method for heating is not particularly limited, and for example, the solvent may be evaporated under an appropriate atmosphere such as atmospheric air, an inert gas including nitrogen and vacuum by using a hot plate or an oven. For the heating temperature and heating time, it is only required to select conditions suitable for a processing step for an electronic device that is aimed at and to select heating conditions by which physical property values of the obtained film satisfy requirements of the electronic device. Conditions for photoirradiation are not particularly limited, either, and it is only required to employ appropriate irradiation energy and irradiation time depending on a film forming material for lithography to be used.

### <Solvent>

A solvent to be used in the composition for film formation for lithography of the present embodiment is not particularly limited as long as it can at least dissolve the compound 0A and the latent base generating agent, and any publicly known solvent can be used appropriately.

Specific examples of the solvent include those described in International Publication No. WO 2013/024779. These solvents can be used alone as one kind, or can be used in combination of two or more kinds.

Among the above solvents, cyclohexanone, propylene glycol monomethyl ether, propylene glycol monomethyl ether acetate, ethyl lactate, methyl hydroxyisobutyrate, or anisole is particularly preferable from the viewpoint of safety.

The content of the solvent is not particularly limited and is preferably 25 to 9,900 parts by mass, more preferably 400 to 7,900 parts by mass, and still more preferably 900 to 4,900 parts by mass based on 100 parts by mass of the total mass of the compound 0A and the latent base generating agent in the material for film formation for lithography, from the viewpoint of solubility and film formation.

The composition for film formation for lithography of the present embodiment may further contain a publicly known additive agent. Examples of the publicly known additive agent include, but are not limited to, ultraviolet absorbers, antifoaming agents, colorants, pigments, nonionic surfactants, anionic surfactants, and cationic surfactants.

### [Resist Film and Resist Pattern Formation Method]

The resist film of the present embodiment is formed by using the composition for film formation for lithography of the present embodiment.

The resist pattern formation method of the present embodiment includes a resist film forming step of forming a resist film on a supporting material by using the composition for film formation for lithography described in the present embodiment, and a development step of irradiating a predetermined region of the resist film formed by the resist film forming step with radiation for development. The resist pattern formation method of the present embodiment can be used for forming various patterns, and is preferably a method for forming an insulating film pattern.

### [Method for Forming Underlayer Film for Lithography and Pattern]

The underlayer film for lithography of the present embodiment is formed by using the composition for film formation for lithography of the present embodiment.

A pattern formation method of the present embodiment has the steps of: forming an underlayer film on a supporting material using the composition for film formation for lithography of the present embodiment (step (A-1)); forming at least one photoresist layer on the underlayer film (step (A-2)); and after the step (A-2), irradiating a predetermined region of the photoresist layer with radiation for development (step (A-3)).

Furthermore, another pattern formation method of the present embodiment has the steps of: forming an underlayer film on a supporting material using the composition for film formation for lithography of the present embodiment (step (B-1)); forming an intermediate layer film on the underlayer film using a resist intermediate layer film material containing a silicon atom (step (B-2)); forming at least one photoresist layer on the intermediate layer film (step (B-3)); after the step (B-3), irradiating a predetermined region of the photoresist layer with radiation for development, thereby forming a resist pattern (step (B-4)); and after the step (B-4), etching the intermediate layer film with the resist pattern as a mask, etching the underlayer film with the obtained intermediate layer film pattern as an etching mask, and etching the supporting material with the obtained underlayer film pattern as an etching mask, thereby forming a pattern on the supporting material (step (B-5)).

The underlayer film for lithography of the present embodiment is not particularly limited by its formation method as long as it is formed from the composition for film formation for lithography of the present embodiment.

A publicly known approach can be applied thereto. The underlayer film can be formed by, for example, applying the composition for film formation for lithography of the present embodiment onto a supporting material by a publicly known coating method or printing method such as spin coating or screen printing, and then removing an organic solvent by volatilization or the like.

It is preferable to perform baking in the formation of the underlayer film, for preventing a mixing event with an upper layer resist while accelerating crosslinking reaction. In this case, the baking temperature is not particularly limited and is preferably in the range of 80 to 450° C., and more preferably 200 to 400° C. The baking time is not particularly limited and is preferably in the range of 10 to 300 seconds. The thickness of the underlayer film can be arbitrarily selected according to required performances and is not particularly limited, but is preferably 30 to 20,000 nm, more preferably 50 to 15,000 nm, and still more preferably 50 to 1000 nm.

After preparing the underlayer film on the supporting material, in the case of a two-layer process, it is preferable to prepare a silicon-containing resist layer or a usual single-layer resist composed of hydrocarbon thereon, and in the case of a three-layer process, it is preferable to prepare a silicon-containing intermediate layer thereon and further prepare a single-layer resist layer not containing silicon thereon. In this case, for a photoresist material for forming this resist layer, a publicly known material can be used.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high supporting material etching resistance as the underlayer film in a process for exposure at 193 nm tends to increase a k value and enhance supporting material reflection. However, the intermediate layer suppresses the reflection so that the supporting material reflection can be 0.5% or less. The intermediate layer having such an antireflection effect is not limited, and polysilsesquioxane that crosslinks by an acid or heat in which a light absorbing group having a phenyl group or a silicon-silicon bond is introduced is preferably used for exposure at 193 nm.

Alternatively, an intermediate layer formed by chemical vapour deposition (CVD) may be used. The intermediate layer highly effective as an antireflection film prepared by CVD is not limited, and, for example, a SiON film is known. In general, the formation of an intermediate layer by a wet process such as spin coating or screen printing is more convenient and more advantageous in cost than CVD. The upper layer resist for a three-layer process may be positive type or negative type, and the same as a single-layer resist generally used can be used.

The underlayer film of the present embodiment can also be used as an antireflection film for usual single-layer resists or an underlying material for suppression of pattern collapse. The underlayer film of the present embodiment is excellent in etching resistance for an underlying process and can be expected to also function as a hard mask for an underlying process.

In the case of forming a resist layer from the above photoresist material, a wet process such as spin coating or screen printing is preferably used, as in the case of forming the above underlayer film. After coating with the resist material by spin coating or the like, prebaking is generally performed. This prebaking is preferably performed at 80 to 180° C. in the range of 10 to 300 seconds. Then, exposure, post-exposure baking (PEB), and development can be performed according to a conventional method to obtain a resist pattern. The thickness of the resist film is not particularly limited, and in general, is preferably 30 to 500 nm and more preferably 50 to 400 nm.

The exposure light can be arbitrarily selected and used according to the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the method mentioned above, pattern collapse is suppressed by the underlayer film of the present embodiment. Therefore, use of the underlayer film of the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process.

The gas etching is suitably etching using oxygen gas. In addition to oxygen gas, an inert gas such as He or Ar, or CO, CO₂, NH₃, SO₂, N₂, NO₂, or H₂ gas may be added. Alternatively, the gas etching may be performed with CO, CO₂, NH₃, N₂, NO₂, or H₂ gas without the use of oxygen gas. Particularly, the latter gas is preferably used for side wall protection in order to prevent the undercut of pattern side walls.

On the other hand, gas etching is also preferably used as the etching of the intermediate layer in a three-layer process. The same gas etching as described in the two-layer process mentioned above is applicable. Particularly, it is preferable to process the intermediate layer in a three-layer process by using chlorofluorocarbon-based gas and using the resist pattern as a mask. Then, as mentioned above, for example, the underlayer film can be processed by oxygen gas etching with the intermediate layer pattern as a mask.

Here, in the case of forming an inorganic hard mask intermediate layer film as the intermediate layer, a silicon oxide film, a silicon nitride film, or a silicon oxynitride film (SiON film) is formed by CVD, ALD, or the like. A method for forming the nitride film is not limited, and for example, a method described in Japanese Patent Application Laid-Open No. 2002-334869 (Patent Literature 6) or WO 2004/066377 (Patent Literature 7) can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is preferably used as the intermediate layer. By imparting effects as an antireflection film to the resist intermediate layer film, there is a tendency that reflection can be effectively suppressed. A specific material for the polysilsesquioxane-based intermediate layer is not limited, and, for example, a material described in Japanese Patent Application Laid-Open No. 2007-226170 (Patent Literature 8) or Japanese Patent Application Laid-Open No. 2007-226204 (Patent Literature 9) can be used.

The subsequent etching of the supporting material can also be performed by a conventional method. For example, the supporting material made of SiO₂ or SiN can be etched mainly using chlorofluorocarbon-based gas, and the supporting material made of p-Si, Al, or W can be etched mainly using chlorine- or bromine-based gas. In the case of etching the supporting material with chlorofluorocarbon-based gas, the silicon-containing resist of the two-layer resist process or the silicon-containing intermediate layer of the three-layer process is stripped at the same time with supporting material processing. On the other hand, in the case of etching the supporting material with chlorine- or bromine-based gas, the silicon-containing resist layer or the silicon-containing intermediate layer is separately stripped and in general, stripped by dry etching using chlorofluorocarbon-based gas after supporting material processing.

A feature of the underlayer film of the present embodiment is that it is excellent in etching resistance of these supporting materials. The supporting material can be arbitrarily selected from publicly known ones and used and is not particularly limited. Examples thereof include Si, α-Si, p-Si, SiO₂, SiN, SiON, W, TiN, and A1.

The supporting material may be a laminate having a film to be processed (supporting material to be processed) on a base material (support). Examples of such a film to be processed include various low-k films such as Si, SiO₂, SiON, SiN, p-Si, α-Si, W, W—Si, Al, Cu, and Al—Si, and stopper films thereof. A material different from that for the base material (support) is generally used. The thickness of the supporting material to be processed or the film to be processed is not particularly limited, and normally, it is preferably approximately 50 to 1,000,000 nm and more preferably 75 to 500,000 nm.

### EXAMPLES

Hereinafter, the present invention will be described in further detail with reference to Synthetic Working Examples, Examples, and Comparative Examples, but the present invention is not limited by these examples in any way.

### [Molecular Weight]

The molecular weight of the synthesized compound was measured by LC-MS analysis using Acquity UPLC/MALDI-Synapt HDMS manufactured by Waters Corporation.

### [Evaluation of Heat Resistance]

EXSTAR 6000 TG-DTA apparatus manufactured by SII NanoTechnology Inc. was used. About 5 mg of a sample was placed in an unsealed container made of aluminum, and the temperature was raised to 500° C. at a temperature increase rate of 10° C./min in a nitrogen gas stream (100 ml/min), thereby measuring the amount of thermogravimetric weight loss. From a practical viewpoint, evaluation A or B described below is preferable. When the evaluation is A or B, the sample has high heat resistance and is applicable to high temperature baking.

### <Evaluation Criteria>

A: The amount of thermogravimetric weight loss at 400° C. is less than 10%

B: The amount of thermogravimetric weight loss at 400° C. is 10% to 25%

C: The amount of thermogravimetric weight loss at 400° C. is greater than 25%

### [Evaluation of Solubility]

A mixed solvent adjusted to have a weight ratio of propylene glycol monomethyl ether acetate (PGMEA) and cyclohexanone (CHN) of 1:1 and the compound and/or the resin were charged into a 50 ml screw bottle and stirred at 23° C. for 1 hour using a magnetic stirrer. Then, the amount of the compound and/or the resin dissolved in the above mixed solvent was measured and the result was evaluated according to the following criteria. From a practical viewpoint, evaluation S, A, or B described below is preferable.

### <Evaluation Criteria>

S: 20% by mass or more and less than 30% by mass

A: 10% by mass or more and less than 20% by mass

B: 5% by mass or more and less than 10% by mass

C: less than 5% by mass

### (Synthetic Working Example 1) Synthesis of BAPP Citraconimide

A container (internal capacity: 100 ml) equipped with a stirrer, a condenser tube, and a burette was prepared. To this container, 4.10 g (10.0 mmol) of 2,2-bis[4-(4-aminophenoxy)phenyl]propane (product name: BAPP, manufactured by Wakayama Seika Kogyo Co., Ltd.), 4.15 g (40.0 mmol) of citraconic anhydride (manufactured by KANTO CHEMICAL CO., INC.), 30 ml of dimethylformamide, and 60 ml of toluene were charged, and 0.4 g (2.3 mmol) of p-toluenesulfonic acid and 0.1 g of a polymerization inhibitor BHT were added, thereby preparing a reaction solution. The reaction solution was stirred at 120° C. for 5 hours to conduct reaction, and the produced water was recovered with a Dean-and-stark trap through azeotropic dehydration. Next, after cooling the reaction solution to 40° C., it was added dropwise into a beaker in which 300 m1 of distilled water was placed to precipitate the product. After filtering the obtained slurry solution, the residue was washed with acetone and subjected to separation and purification with column chromatography to acquire 3.76 g of the target compound (BAPP citraconimide) represented by the following formula:

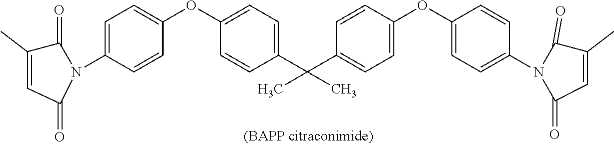

The following peaks were found by 400 MHz-¹H-NMR, and the compound was confirmed to have a chemical structure of the above formula.

¹H-NMR: (d-DMSO, Internal Standard TMS)

δ (ppm) 6.8-7.4 (16H, Ph-H), 6.7 (2H, —CH═C) 2.1 (6H, C—CH3), 1.6 (6H, —C(CH3)2). As a result of measuring the molecular weight of the obtained compound by the above method, it was 598.

### (Synthetic Working Example 2) Synthesis of m-BAPP Bismaleimide

A container (internal capacity: 100 ml) equipped with a stirrer, a condenser tube, and a burette was prepared. To this container, 4.10 g (10.0 mmol) of 2,2-bis[4-(3-aminophenoxy)phenyl]propane (product name: m-BAPP, manufactured by TECNO CHEM CO., LTD.), 2.15 g (22.0 mmol) of maleic anhydride (manufactured by KANTO CHEMICAL CO., INC.), 40 ml of dimethylformamide, and 30 ml of m-xylene were charged, and 0.4 g (2.3 mmol) of p-toluenesulfonic acid was added, thereby preparing a reaction solution. The reaction solution was stirred at 130° C. for 4.0 hours to conduct reaction, and the produced water was recovered with a Dean-and-stark trap through azeotropic dehydration. Next, the reaction solution was cooled to 40° C. and it was then added dropwise into a beaker in which 300 ml of distilled water was placed to precipitate the product. After filtering the obtained slurry solution, the residue was washed with methanol and subjected to separation and purification with column chromatography to acquire 3.10 g of the target compound (m-BAPP bismaleimide) represented by the following formula:

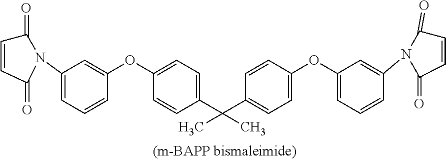 [SMILES: CC(C)(c1ccc(Oc2cccc(N3C(=O)C=CC3=O)c2)cc1)c1ccc(Oc2cccc(N3C(=O)C=CC3=O)c2)cc1]

The following peaks were found by 400 MHz-¹H-NMR, and the compound was confirmed to have a chemical structure of the above formula.

¹H-NMR: (d-DMSO, Internal Standard TMS)

δ (ppm) 6.8-7.4 (16H, Ph-H), 6.9 (4H, —CH═CH), 1.6 (6H, —C(CH3)2). As a result of measuring the molecular weight of the obtained compound by the above method, it was 598.

### (Synthetic Working Example 3) Synthesis of m-BAPP Citraconimide

A container (internal capacity: 100 ml) equipped with a stirrer, a condenser tube, and a burette was prepared. To this container, 4.10 g (10.0 mmol) of 2,2-bis[4-(3-aminophenoxy)phenyl]propane (product name: m-BAPP, manufactured by TECNO CHEM CO., LTD.), 4.15 g (40.0 mmol) of citraconic anhydride (manufactured by KANTO CHEMICAL CO., INC.), 30 ml of dimethylformamide, and 60 ml of toluene were charged, and 0.4 g (2.3 mmol) of p-toluenesulfonic acid and 0.1 g of a polymerization inhibitor BHT were added, thereby preparing a reaction solution. The reaction solution was stirred at 120° C. for 5 hours to conduct reaction, and the produced water was recovered with a Dean-and-stark trap through azeotropic dehydration. Next, after cooling the reaction solution to 40° C., it was added dropwise into a beaker in which 300 ml of distilled water was placed to precipitate the product. After filtering the obtained slurry solution, the residue was washed with acetone and subjected to separation and purification with column chromatography to acquire 3.52 g of the target compound (m-BAPP citraconimide) represented by the following formula:

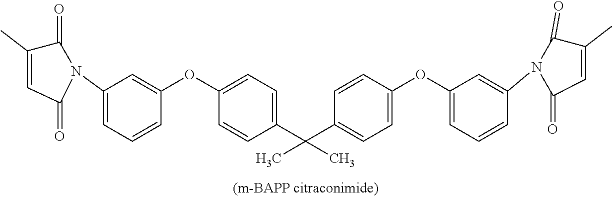

The following peaks were found by 400 MHz-¹H-NMR, and the compound was confirmed to have a chemical structure of the above formula.

¹H-NMR: (d-DMSO, Internal Standard TMS)

δ (ppm) 6.8-7.4 (16H, Ph-H), 6.7 (2H, —CH═C), 2.0 (6H, C—CH3), 1.6 (6H, —C(CH3)₂). As a result of measuring the molecular weight of the obtained compound by the above method, it was 598.

### (Synthetic Working Example 4) Synthesis of BMI Citraconimide Resin

A container (internal capacity: 100 ml) equipped with a stirrer, a condenser tube, and a burette was prepared. To this container, 2.4 g of diaminodiphenylmethane oligomers obtained by following up on Synthetic Example 1 in Japanese Patent Application Laid-Open No. 2001-26571, 4.56 g (44.0 mmol) of citraconic anhydride (manufactured by KANTO CHEMICAL CO., INC.), 40 ml of dimethylformamide, and 60 ml of toluene were charged, and 0.4 g (2.3 mmol) of p-toluenesulfonic acid and 0.1 g of a polymerization inhibitor BHT were added, thereby preparing a reaction solution. The reaction solution was stirred at 110° C. for 8.0 hours to conduct reaction, and the produced water was recovered with a Dean-and-stark trap through azeotropic dehydration. Next, the reaction solution was cooled to 40° C. and it was then added dropwise into a beaker in which 300 ml of distilled water was placed to precipitate the product. After filtering the obtained slurry solution, the residue was washed with methanol to acquire 4.7 g of a citraconimide resin (BMI citraconimide resin) represented by the following formula:

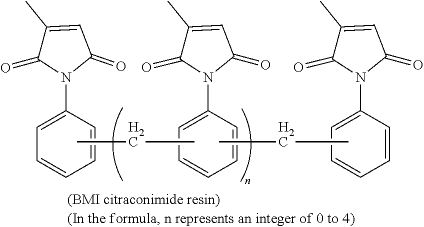

Note that, as a result of measuring the molecular weight by the above method, it was 446.

### (Synthetic Working Example 5) Synthesis of BAN Citraconimide Resin

A container (internal capacity: 100 ml) equipped with a stirrer, a condenser tube, and a burette was prepared. To this container, 6.30 g of a biphenyl aralkyl-based polyaniline resin (product name: BAN, manufactured by Nippon Kayaku Co., Ltd.), 4.56 g (44.0 mmol) of citraconic anhydride (manufactured by KANTO CHEMICAL CO., INC.), 40 ml of dimethylformamide, and 60 ml of toluene were charged, and 0.4 g (2.3 mmol) of p-toluenesulfonic acid and 0.1 g of a polymerization inhibitor BHT were added, thereby preparing a reaction solution. The reaction solution was stirred at 110° C. for 6.0 hours to conduct reaction, and the produced water was recovered with a Dean-and-stark trap through azeotropic dehydration. Next, the reaction solution was cooled to 40° C., and it was then added dropwise into a beaker in which 300 ml of distilled water was placed to precipitate the product. After filtering the obtained slurry solution, the residue was washed with methanol and subjected to separation and purification with column chromatography to acquire 5.5 g of the target compound (BAN citraconimide resin) represented by the following formula:

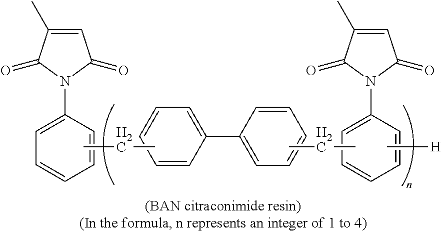

### (Synthetic Working Example 6) Synthesis of Monomer-Removed BMI Maleimide Resin

A container (internal capacity: 300 ml) equipped with a distillation column capable of retaining heat was prepared. To this container, 100 g of diaminodiphenylmethane oligomers obtained by following up on Synthetic Example 1 in Japanese Patent Application Laid-Open No. 2001-26571 were charged, and water and low boiling impurities were first distilled off by atmospheric distillation. The degree of reduced pressure was gradually increased to 30 Pa, and the diaminodiphenylmethane monomers were mainly removed at a column top temperature of 200 to 230° C. to obtain 32 g of monomer-removed diaminomethane oligomers.

Next, 2.4 g of monomer-removed diaminodiphenylmethane oligomers obtained above were charged into a container (internal capacity: 200 ml) equipped with a stirrer and a condenser tube, then 4.56 g (44.0 mmol) of maleic anhydride (manufactured by KANTO CHEMICAL CO., INC.), 40 ml of dimethylformamide, and 60 ml of toluene were charged, and 0.4 g (2.3 mmol) of p-toluenesulfonic acid and 0.1 g of a polymerization inhibitor BHT were added, thereby preparing a reaction solution. The reaction solution was stirred at 100° C. for 6.0 hours to conduct reaction, and the produced water was recovered with a Dean-and-stark trap through azeotropic dehydration. Next, the reaction solution was cooled to 40° C., and it was then added dropwise into a beaker in which 300 ml of distilled water was placed to precipitate the product. After filtering the obtained slurry solution, the residue was washed with methanol to acquire 5.6 g of a monomer-removed BMI maleimide resin represented by the following formula. As a result of measuring the molecular weight of the resin by the above method, it was 836.

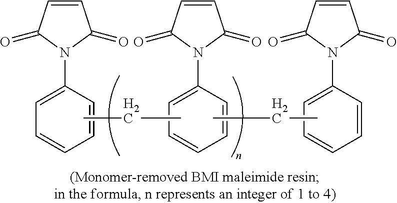

### (Synthetic Working Example 7) Synthesis of Monomer-Removed BMI Citraconimide Resin

A container (internal capacity: 300 ml) equipped with a distillation column capable of retaining heat was prepared. To this container, 100 g of diaminodiphenylmethane oligomers obtained by following up on Synthetic Example 1 in Japanese Patent Application Laid-Open No. 2001-26571 were charged, and water and low boiling impurities were first distilled off by atmospheric distillation. The degree of reduced pressure was gradually increased to 30 Pa, and the diaminodiphenylmethane monomers were mainly removed at a column top temperature of 200 to 230° C. to obtain 32 g of monomer-removed diaminomethane oligomers.

Next, 2.4 g of monomer-removed diaminodiphenylmethane oligomers obtained above were charged into a container (internal capacity: 200 ml) equipped with a stirrer and a condenser tube, then 4.56 g (44.0 mmol) of citraconic anhydride (manufactured by KANTO CHEMICAL CO., INC.), 40 ml of dimethylformamide, and 60 ml of toluene were charged, and 0.4 g (2.3 mmol) of p-toluenesulfonic acid and 0.1 g of a polymerization inhibitor BHT were added, thereby preparing a reaction solution. The reaction solution was stirred at 110° C. for 8.0 hours to conduct reaction, and the produced water was recovered with a Dean-and-stark trap through azeotropic dehydration. Next, the reaction solution was cooled to 40° C. and it was then added dropwise into a beaker in which 300 ml of distilled water was placed to precipitate the product. After filtering the obtained slurry solution, the residue was washed with methanol to acquire 6.3 g of a monomer-removed BMI citraconimide resin represented by the following formula. As a result of measuring the molecular weight of the resin by the above method, it was 857.

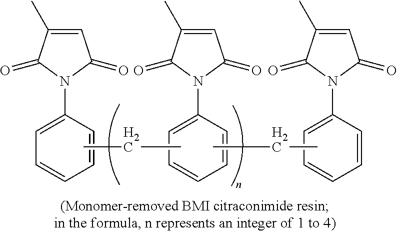

### Example 1

As a maleimide compound, 9 parts by mass of a bismaleimide (BMI-80; manufactured by K⋅I Chemical Industry Co., LTD.) represented by the formula described below and 1 part by mass of a latent base generating agent (WPBG-300; manufactured by FUJIFILM Wako Pure Chemical Corporation) were used to prepare a film forming material for lithography.

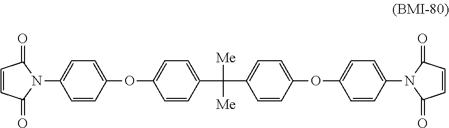 [SMILES: CC(C)(c1ccc(Oc2ccc(N3C(=O)C=CC3=O)cc2)cc1)c1ccc(Oc2ccc(N3C(=O)C=CC3=O)cc2)cc1]

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have sufficient solubility.

To 10 parts by mass of the film forming material for lithography, 90 parts by mass of the above mixed solvent was added, and the resultant mixture was stirred with a stirrer for at least 3 hours or longer at room temperature to prepare a composition for film formation for lithography.

### Example 2

As a maleimide compound, 9 parts by mass of the m-BAPP bismaleimide obtained in Synthetic Working Example 2 and 1 part by mass of a latent base generating agent (WPBG-300; manufactured by FUJIFILM Wako Pure Chemical Corporation) were used to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 10% by mass or more and less than 20% by mass (evaluation A), and the obtained film forming material for lithography was evaluated to have excellent solubility.

The same operations as in the above Example 1 were carried out, thereby preparing a composition for film formation for lithography.

### Example 3

As a bismaleimide resin, 9 parts by mass of BMI maleimide oligomers (BMI-2300; manufactured by Daiwakasei Industry Co., LTD.) represented by the formula described below and 1 part by mass of a latent base generating agent (WPBG-300; manufactured by FUJIFILM Wako Pure Chemical Corporation) were used to prepare a film forming material for lithography.

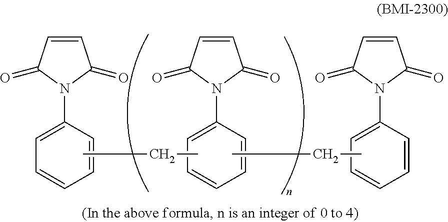

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 10% by mass or more and less than 20% by mass (evaluation A), and the obtained film forming material for lithography was evaluated to have excellent solubility.

The same operations as in the above Example 1 were carried out, thereby preparing a composition for film formation for lithography.

### Example 4

As a bismaleimide resin, 9 parts by mass of a biphenyl aralkyl-based maleimide resin (MIR-3000-L; manufactured by Nippon Kayaku Co., Ltd.) represented by the formula described below and 1 part by mass of a latent base generating agent (WPBG-300; manufactured by FUJIFILM Wako Pure Chemical Corporation) were used to prepare a film forming material for lithography.

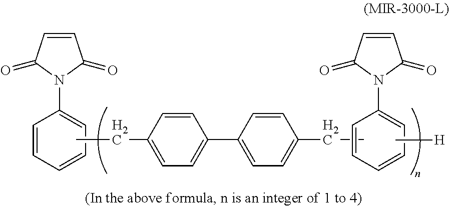

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 10% by mass or more and less than 20% by mass (evaluation A), and the obtained film forming material for lithography was evaluated to have excellent solubility.

The same operations as in the above Example 1 were carried out, thereby preparing a composition for film formation for lithography.

### Example 5

As a biscitraconimide compound, 9 parts by mass of the BAPP citraconimide obtained in Synthetic Working Example 1 and 1 part by mass of a latent base generating agent (WPBG-300; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have good solubility.

The same operations as in the above Example 1 were carried out, thereby preparing a composition for film formation for lithography.

### Example 6

As a biscitraconimide compound, 9 parts by mass of the m-BAPP citraconimide obtained in Synthetic Working Example 3 and 1 part by mass of a latent base generating agent (WPBG-300; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have good solubility.

The same operations as in the above Example 1 were carried out, thereby preparing a composition for film formation for lithography.

### Example 7

As a citraconimide resin, 9 parts by mass of the BMI citraconimide resin obtained in Synthetic Working Example 4 and 1 part by mass of a latent base generating agent (WPBG-300; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 8

As a citraconimide resin, 9 parts by mass of the BAN citraconimide resin obtained in Synthetic Working Example 5 and 1 part by mass of a latent base generating agent (WPBG-300; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 9

As a maleimide compound, 9 parts by mass of the above BMI-80 and 1 part by mass of a latent base generating agent (WPBG-266; manufactured by FUJIFILM Wako Pure Chemical Corporation) were used to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have sufficient solubility.

The same operations as in the above Example 1 were carried out, thereby preparing a composition for film formation for lithography.

### Example 10

As a maleimide compound, 9 parts by mass of the above m-BAPP bismaleimide and 1 part by mass of a latent base generating agent (WPBG-266; manufactured by FUJIFILM Wako Pure Chemical Corporation) were used to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have sufficient solubility.

The same operations as in the above Example 1 were carried out, thereby preparing a composition for film formation for lithography.

### Example 11

As a bismaleimide resin, 9 parts by mass of the above BMI maleimide oligomers and 1 part by mass of a latent base generating agent (WPBG-266; manufactured by FUJIFILM Wako Pure Chemical Corporation) were used to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 10% by mass or more and less than 20% by mass (evaluation A), and the obtained film forming material for lithography was evaluated to have excellent solubility.

The same operations as in the above Example 1 were carried out, thereby preparing a composition for film formation for lithography.

### Example 11A

As a maleimide resin, 9 parts by mass of the monomer-removed BMI maleimide resin obtained in Synthetic Working Example 6 and 1 part by mass of a latent base generating agent (WPBG-266; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 12

As a bismaleimide resin, 9 parts by mass of the above MIR-3000-L and 1 part by mass of a latent base generating agent (WPBG-266; manufactured by FUJIFILM Wako Pure Chemical Corporation) were used to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 10% by mass or more and less than 20% by mass (evaluation A), and the obtained film forming material for lithography was evaluated to have excellent solubility.

The same operations as in the above Example 1 were carried out, thereby preparing a composition for film formation for lithography.

### Example 13

As a biscitraconimide compound, 9 parts by mass of the BAPP citraconimide obtained in Synthetic Working Example 1 and 1 part by mass of a latent base generating agent (WPBG-266; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have good solubility.

The same operations as in the above Example 1 were carried out, thereby preparing a composition for film formation for lithography.

### Example 14

As a biscitraconimide compound, 9 parts by mass of the m-BAPP citraconimide obtained in Synthetic Working Example 3 and 1 part by mass of a latent base generating agent (WPBG-266; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have good solubility.

The same operations as in the above Example 1 were carried out, thereby preparing a composition for film formation for lithography.

### Example 15

As a citraconimide resin, 9 parts by mass of the BMI citraconimide resin obtained in Synthetic Working Example 4 and 1 part by mass of a latent base generating agent (WPBG-266; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 15A

As a citraconimide resin, 9 parts by mass of the monomer-removed BMI citraconimide resin obtained in Synthetic Working Example 7 and 1 part by mass of a latent base generating agent (WPBG-266; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 16

As a citraconimide resin, 9 parts by mass of the BAN citraconimide resin obtained in Synthetic Working Example 5 and 1 part by mass of a latent base generating agent (WPBG-266; manufactured by FUJIFILM Wako Pure Chemical Corporation) were compounded to prepare a film forming material for lithography.

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 17

As a maleimide compound, 9 parts by mass of BMI-80 and 1 part by mass of the latent base generating agent WPBG-300 were used. In addition, 2 parts by mass of benzoxazine (BF-BXZ; manufactured by KONISHI CHEMICAL IND. CO., LTD.) represented by the formula described above was compounded as a crosslinking agent to prepare a film forming material for lithography.

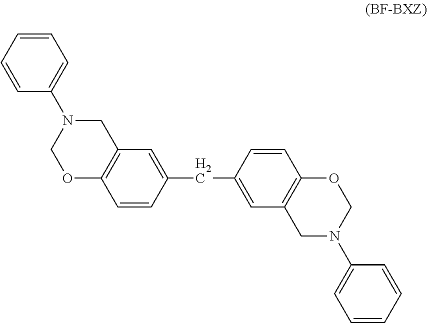 [SMILES: c1ccc(N2COc3ccc(Cc4ccc5c(c4)CN(c4ccccc4)CO5)cc3C2)cc1]

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 18

As a maleimide compound, 9 parts by mass of BMI-80 and 1 part by mass of the latent base generating agent WPBG-300 were used. In addition, 2 parts by mass of a biphenyl aralkyl-based epoxy resin (NC-3000-L; manufactured by Nippon Kayaku Co., Ltd.) represented by the following formula was used as a crosslinking agent to prepare a film forming material for lithography.

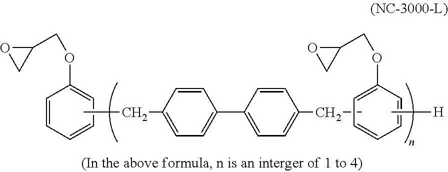

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 10% by mass or more and less than 20% by mass (evaluation A), and the obtained film forming material for lithography was evaluated to have excellent solubility.

The same operations as in the above Example 1 were carried out, thereby preparing a composition for film formation for lithography.

### Example 19

As a maleimide compound, 9 parts by mass of BMI-80 and 1 part by mass of the latent base generating agent WPBG-300 were used. In addition, 2 parts by mass of a diallylbisphenol A-based cyanate (DABPA-CN; manufactured by MITSUBISHI GAS CHEMICAL COMPANY, INC.) represented by the following formula was compounded as a crosslinking agent to prepare a film forming material for lithography.

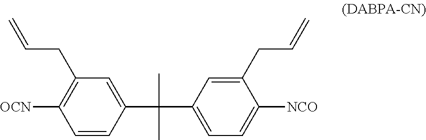

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 20

As a maleimide compound, 9 parts by mass of BMI-80 and 1 part by mass of the latent base generating agent WPBG-300 were used. In addition, 2 parts by mass of a diallylbisphenol A (BPA-CA; manufactured by KONISHI CHEMICAL IND. CO., LTD.) represented by the following formula was compounded as a crosslinking agent to prepare a film forming material for lithography.

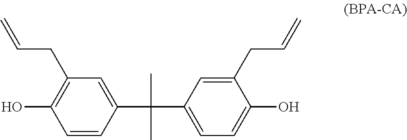 [SMILES: C=CCc1cc(C(C)(C)c2ccc(O)c(CC=C)c2)ccc1O]

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 21

As a maleimide compound, 9 parts by mass of BMI-80 and 1 part by mass of the latent base generating agent WPBG-300 were used. In addition, 2 parts by mass of a diphenylmethane-based allylphenolic resin (APG-1; manufactured by Gun Ei Chemical Industry Co., Ltd.) represented by the formula described below was used as the crosslinking agent to prepare a film forming material for lithography.

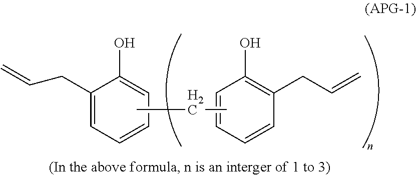

As a result of thermogravimetry, the amount of thermogravimetric weight loss at 400° C. of the obtained film forming material for lithography was less than 10% (evaluation A). In addition, as a result of evaluation of solubility in a mixed solvent of PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 22

As a maleimide compound, 9 parts by mass of BMI-80 and 1 part by mass of the latent base generating agent WPBG-300 were used. In addition, 2 parts by mass of a diphenylmethane-based propenylphenolic resin (APG-2; manufactured by Gun Ei Chemical Industry Co., Ltd.) represented by the formula described below was used as the crosslinking agent to prepare a film forming material for lithography.

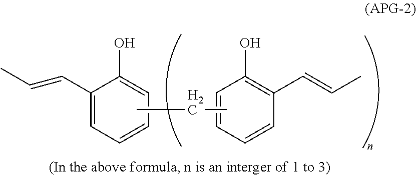

As a result of thermogravimetry, the amount of thermogravimetric weight loss at 400° C. of the obtained film forming material for lithography was less than 10% (evaluation A). In addition, as a result of evaluation of solubility in PGMEA/CHN, the solubility was 20% by mass or more (evaluation S) and the obtained film forming material for lithography was evaluated to have excellent solubility.

The same operations as in the above Example 1 were carried out, thereby preparing a composition for film formation for lithography.

### Example 23

As a maleimide compound, 9 parts by mass of BMI-80 and 1 part by mass of the latent base generating agent WPBG-300 were used. In addition, 2 parts by mass of 4,4′-diaminodiphenylmethane (DDM; manufactured by Tokyo Chemical Industry Co., Ltd.) represented by the formula described below was used as the crosslinking agent to prepare a film forming material for lithography.

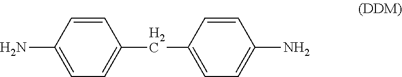 [SMILES: Nc1ccc(Cc2ccc(N)cc2)cc1]

As a result of thermogravimetry, the amount of thermogravimetric weight loss at 400° C. of the obtained film forming material for lithography was less than 10% (evaluation A). In addition, as a result of evaluation of solubility in PGMEA/CHN, the solubility was 20% by mass or more (evaluation S) and the obtained film forming material for lithography was evaluated to have excellent solubility. In addition, the same operations as in Example 1 were carried out, thereby preparing a composition for film formation for lithography.

### Comparative Examples 1 to 6

A film forming material for lithography was prepared in the same manner as in Examples 1, 3 to 5, 7 and 8 except that 1 part by mass of 2,4,5-triphenylimidazole (TPIZ; manufactured by Shikoku Chemicals Corporation) was compounded as a curing accelerator instead of the latent base generating agent WPBG-300. In addition, the same operations as in Example 1 were carried out, thereby preparing a composition for film formation for lithography.

### Comparative Examples 7 to 13

A film forming material for lithography was prepared in the same manner as in Examples 17 to 23 except that 1 part by mass of 2,4,5-triphenylimidazole (TPIZ; manufactured by Shikoku Chemicals Corporation) was compounded as a curing accelerator instead of the latent base generating agent WPBG-300. In addition, the same operations as in Example 1 were carried out, thereby preparing a composition for film formation for lithography.

### Examples 24 to 37

Compositions for film formation for lithography were each prepared according to the composition shown in Table 2.

### <Evaluation of Compositions for Film Formation for Lithography of Examples 1 to 23 and Comparative Examples

1 to 13>[Evaluation of storage stability]

After storing the composition for film formation for lithography in a thermostatic bath at 40° C. for 1 month, the hue change ΔYI of the solution was measured by using a colorimeter/turbidimeter (manufactured by Nippon Denshoku Industries Co., Ltd.) and a quartz glass cell with an optical path length of 1 cm. Storage stability was evaluated according to the evaluation criteria shown below.

### (Evaluation Criteria)

S: After storage at 40° C. for 1 month ΔYI≤1.0

A: After storage at 40° C. for 1 month 1.0<ΔYI≤3.0

B: After storage at 40° C. for 1 month 3.0<ΔYI

### [Evaluation of Curability]

A silicon supporting material was spin coated with a composition for film formation for lithography, and then baked at 240° C. for 60 seconds. Then, the film thickness of the resultant coated film was measured. Thereafter, the silicon supporting material was immersed in a mixed solvent of 70% PGMEA/30% PGME for 60 seconds, the adhered solvent was removed with an Aero Duster, and the supporting material was then subjected to solvent drying at 110° C. From the difference in film thickness before and after the immersion, the decreasing rate of film thickness (%) was calculated, and the curability of each underlayer film was evaluated according to the evaluation criteria shown below.

### (Evaluation Criteria)

S: Decreasing rate of film thickness before and after solvent immersion≤1% (Good)

A: Decreasing rate of film thickness before and after solvent immersion≤5% (Partially good)

B: Decreasing rate of film thickness before and after solvent immersion≤10%

C: Decreasing rate of film thickness before and after solvent immersion>10%

### [Evaluation of Film Heat Resistance]

The underlayer film after the curing baking at 240° C. in the evaluation of curability was further baked at 450° C. for 120 seconds. From the difference in film thickness before and after the baking, the decreasing rate of film thickness (%) was calculated, and the film heat resistance of each underlayer film was evaluated according to the evaluation criteria shown below.

### (Evaluation Criteria)

SS: Decreasing rate of film thickness after baking at 450° C.≤5%

S: Decreasing rate of film thickness before and after baking at 450° C.≤10% (Good)

A: Decreasing rate of film thickness before and after baking at 450° C.≤15% (Partially good)

B: Decreasing rate of film thickness before and after baking at 450° C.≤20%

C: Decreasing rate of film thickness before and after baking at 450° C.>20%

### [Evaluation of Flatness]

Onto a SiO₂ supporting material having difference in level on which trenches with a width of 100 nm, a pitch of 150 nm, and a depth of 150 nm (aspect ratio: 1.5) and trenches with a width of 5 μm and a depth of 180 nm (open space) were mixedly present, each of the compositions for film formation for lithography was coated. Subsequently, it was calcined at 240° C. for 120 seconds under the air atmosphere to form a resist underlayer film having a film thickness of 200 nm. The shape of this resist underlayer film was observed with a scanning electron microscope (“S-4800” from Hitachi High-Technologies Corporation), and the difference between the maximum value and the minimum value of the film thickness of the resist underlayer film on the trench or space (ΔFT) was measured. Flatness on a supporting material having difference in level was evaluated according to the evaluation criteria shown below.

### (Evaluation Criteria)

S: ΔFT<10 nm (best flatness)

A: 10 nm≤ΔFT<20 nm (good flatness)

B: 20 nm≤ΔFT<40 nm (partially good flatness)

C: 40 nm≤ΔFT (poor flatness)

### Evaluation of Compositions for Film Formation for Lithography of Examples 24 to 37

### [Evaluation of Storage Stability]

The procedures performed were the same as those in the evaluation of the compositions for film formation for lithography of Examples 1 to 23 and Comparative Examples 1 to 13.

### [Evaluation of Curability]

A silicon supporting material was spin coated with a composition for film formation for lithography, and then baked at 150° C. for 60 seconds to remove the solvent in the coated film. Subsequently, the film was cured using a high pressure mercury lamp with an accumulated light exposure of 1500 mJ/cm² and an irradiation time of 60 seconds, and then the film thickness of the coated film was measured. Thereafter, the silicon supporting material was immersed in a mixed solvent of 70% PGMEA/30% PGME for 60 seconds, the adhered solvent was removed with an Aero Duster, and the supporting material was then subjected to solvent drying at 110° C. From the difference in film thickness before and after the immersion, the decreasing rate of film thickness (%) was calculated, and the curability of each underlayer film was evaluated according to the evaluation criteria shown below.

### (Evaluation Criteria)

S: Decreasing rate of film thickness before and after solvent immersion≤1% (Good)

A: Decreasing rate of film thickness before and after solvent immersion≤5% (Partially good)

B: Decreasing rate of film thickness before and after solvent immersion≤10%

C: Decreasing rate of film thickness before and after solvent immersion>10%

### [Evaluation of Film Heat Resistance]

The underlayer films after the curing with a high pressure mercury lamp in the evaluation of curability were further baked at 450° C. for 120 seconds, and from the difference in film thickness before and after the baking, the decreasing rate of film thickness (%) was calculated to evaluate the film heat resistance of each underlayer film according to the evaluation criteria shown below.

### (Evaluation Criteria)

SS: Decreasing rate of film thickness before and after baking at 450° C.≤5%

S: Decreasing rate of film thickness before and after baking at 450° C.≤10% (Good)

A: Decreasing rate of film thickness before and after baking at 450° C.≤15% (Partially good)

B: Decreasing rate of film thickness before and after baking at 450° C.≤20%

C: Decreasing rate of film thickness before and after baking at 450° C.>20%

### [Evaluation of Flatness]

The procedures performed were the same as those in the evaluation of the compositions for film formation for lithography of Examples 1 to 23 and Comparative Examples 1 to 13.

TABLE 1

| | Maleimide | Crosslinking | Curing | | Storage | | Film heat | |
|---|---|---|---|---|---|---|---|---|
| | Citraconimide | agent | accelerator | Solvent | stability | Curability | resistance | Flatness |
| Example | BMI-80 | — | WPBG-300 | PGMEA/ | S | S | S | A |
| 1 | (9) | | (1) | CHN | | | | |
| | | | | (90) | | | | |
| Example | m-BAPP | — | WPBG-300 | PGMEA/ | S | S | S | A |
| 2 | bismaleimide | (1) | N | CHN | | | | |
| | (9) | | | (90) | | | | |
| Example | BMI-2300 | — | WPBG-300 | PGMEA/ | S | S | S | A |
| 3 | (9) | | (1) | CHN | | | | |
| | | | | (90) | | | | |
| Example | MIR-3000-L | — | WPBG-300 | PGMEA/ | S | S | S | A |
| 4 | (9) | | (1) | CHN | | | | |
| | | | | (90) | | | | |
| Example | BAPP | — | WPBG-300 | PGMEA/ | S | A | A | S |
| 5 | citraconimide | | (1) | CHN | | | | |
| | (9) | | | (90) | | | | |
| Example | m-BAPP | — | WPBG-300 | PGMEA/ | S | A | A | S |
| 6 | citraconimide | | (1) | CHN | | | | |
| | (9) | | | (90) | | | | |
| Example | BMI | — | WPBG-300 | PGMEA/ | S | A | A | S |
| 7 | citraconimide | | (1) | CHN | | | | |
| | (9) | | | (90) | | | | |
| Example | BAN | — | WPBG-300 | PGMEA/ | S | A | A | S |
| 8 | citraconimide | | (1) | CHN | | | | |
| | (9) | | | (90) | | | | |
| Example | BMI-80 | — | WPBG-266 | PGMEA/ | A | S | S | A |
| 9 | (9) | | (1) | CHN | | | | |
| | | | | (90) | | | | |
| Example | m-BAPP | — | WPBG-266 | PGMEA/ | A | S | S | A |
| 10 | bismaleimide | | (1) | CHN | | | | |
| | (9) | | | (90) | | | | |
| Example | BMI-2300 | — | WPBG-266 | PGMEA/ | A | S | S | A |
| 11 | (9) | | (1) | CHN | | | | |
| | | | | (90) | | | | |
| Example | Monomer- | — | WPBG-266 | PGMEA/ | A | S | SS | S |
| 11A | removed | | (1) | CHN | | | | |
| | BMI-2300 | | | (90) | | | | |
| | (9) | | | | | | | |
| Example | MIR-3000-L | — | WPBG-266 | PGMEA/ | A | S | S | A |
| 12 | (9) | | (1) | CHN | | | | |
| | | | | (90) | | | | |
| Example | BAPP | — | WPBG-266 | PGMEA/ | A | A | A | S |
| 13 | citraconimide | | (1) | CHN | | | | |
| | (9) | | | (90) | | | | |
| Example | m-BAPP | — | WPBG-266 | PGMEA/ | A | A | A | S |
| 14 | citraconimide | | (1) | CHN | | | | |
| | (9) | | | (90) | | | | |
| Example | BMI | — | WPBG-266 | PGMEA/ | A | A | A | S |
| 15 | citraconimide | | (1) | CHN | | | | |
| | (9) | | | (90) | | | | |
| Example | Monomer- | — | WPBG-266 | PGMEA/ | A | A | S | S |
| 15A | removed | | (1) | CHN | | | | |
| | BMI | | | (90) | | | | |
| | citraconimide | | | | | | | |
| | (9) | | | | | | | |
| Example | BAN | | WPBG-266 | PGMEA/ | A | A | A | S |
| 16 | citraconimide | | (1) | CHN | | | | |
| | (9) | | | (90) | | | | |
| Example | BMI-80 | BF-BXZ | WPBG-300 | PGMEA/ | A | S | S | A |
| 17 | (9) | (2) | (1) | CHN | | | | |
| | | | | (90) | | | | |
| Example | BMI-80 | NC-3000-L | WPBG-300 | PGMEA/ | A | S | S | A |
| 18 | (9) | (2) | (1) | CHN | | | | |
| | | | | (90) | | | | |
| Example | BMI-80 | DABPA-CN | WPBG-300 | PGMEA/ | A | S | S | A |
| 19 | (9) | (2) | (1) | CHN | | | | |
| | | | | (90) | | | | |
| Example | BMI-80 | BPA-CA | WPBG-300 | PGMEA/ | A | S | S | A |
| 20 | (9) | (2) | (1) | CHN | | | | |
| | | | | (90) | | | | |
| Example | BMI-80 | APG-1 | WPBG-300 | PGMEA/ | A | S | S | A |
| 21 | (9) | (2) | (1) | CHN | | | | |
| | | | | (90) | | | | |
| Example | BMI-80 | APG-2 | WPBG-300 | PGMEA/ | A | S | S | A |
| 22 | (9) | (2) | (1) | CHN | | | | |
| | | | | (90) | | | | |
| Example | BMI-80 | DDM | WPBG-300 | PGMEA/ | A | S | S | A |
| 23 | (9) | (2) | (1) | CHN | | | | |
| | | | | (90) | | | | |
| Comparative | BMI-80 | — | TPIZ | PGMEA/ | B | S | A | S |
| Example | (9) | | (1) | CHN | | | | |
| 1 | | | | (90) | | | | |
| Comparative | BMI-2300 | — | TPIZ | PGMEA/ | B | S | A | S |
| Example | (9) | | (1) | CHN | | | | |
| 2 | | | | (90) | | | | |
| Comparative | MIR-3000-L | — | TPIZ | PGMEA/ | B | S | A | S |
| Example | (9) | | (1) | CHN | | | | |
| 3 | | | | (90) | | | | |
| Comparative | BAPP | — | TPIZ | PGMEA/ | B | A | C | S |
| Example | citraconimide | | (1) | CHN | | | | |
| 4 | (9) | | | (90) | | | | |
| Comparative | BMI | — | TPIZ | PGMEA/ | B | A | C | S |
| Example | citraconimide | | (1) | CHN | | | | |
| 5 | (9) | | | (90) | | | | |
| Comparative | BAN | — | TPIZ | PGMEA/ | B | S | C | A |
| Example | citraconimide | | (1) | CHN | | | | |
| 6 | (9) | | | (90) | | | | |
| Comparative | BMI-80 | BF-BXZ | TPIZ | PGMEA/ | B | A | B | B |
| Example | (9) | (2) | (1) | CHN | | | | |
| 7 | | | | (90) | | | | |
| Comparative | BMI-80 | NC-3000-L | TPIZ | PGMEA/ | B | A | B | B |
| Example | (9) | (2) | (1) | CHN | | | | |
| 8 | | | | (90) | | | | |
| Comparative | BMI-80 | DABPA-CN | TPIZ | PGMEA/ | B | A | B | B |
| Example | (9) | (2) | (1) | CHN | | | | |
| 9 | | | | (90) | | | | |
| Comparative | BMI-80 | BPA-CA | TPIZ | PGMEA/ | B | A | B | B |
| Example | (9) | (2) | (1) | CHN | | | | |
| 10 | | | | (90) | | | | |
| Comparative | BMI-80 | APG-1 | TPIZ | PGMEA/ | B | A | B | B |
| Example | (9) | (2) | (1) | CHN | | | | |
| 11 | | | | (90) | | | | |
| Comparative | BMI-80 | APG-2 | TPIZ | PGMEA/ | B | A | B | B |
| Example | (9) | (2) | (1) | CHN | | | | |
| 12 | | | | (90) | | | | |
| Comparative | BMI-80 | DDM | TPIZ | PGMEA/ | B | A | B | B |
| Example | (9) | (2) | (1) | CHN | | | | |
| 13 | | | | (90) | | | | |

Number in brackets represents part by mass of each component

TABLE 2

| | Maleimide | Crosslinking | Curing | | Storage | | Film heat | |
|---|---|---|---|---|---|---|---|---|
| | Citraconimide | agent | accelerator | Solvent | stability | Curability | resistance | Flatness |
| Example | BMI-80 | — | WPBG-300 | PGMEA/ | S | S | S | A |
| 24 | (9) | | (1) | CHN | | | | |
| | | | | (90) | | | | |
| Example | m-BAPP | — | WPBG-300 | PGMEA/ | S | S | S | A |
| 25 | bismaleimide | | (1) | CHN | | | | |
| | (9) | | | (90) | | | | |
| Example | BMI-2300 | — | WPBG-300 | PGMEA/ | S | S | S | A |
| 26 | (9) | | (1) | CHN | | | | |
| | | | | (90) | | | | |
| Example | Monomer- | — | WPBG-300 | PGMEA/ | S | S | SS | A |
| 26A | removed | | (1) | CHN | | | | |
| | BMI | | | (90) | | | | |
| | maleimide | | | | | | | |
| | (9) | | | | | | | |
| Example | MIR-3000-L | — | WPBG-300 | PGMEA/ | S | S | S | A |
| 27 | (9) | | (1) | CHN | | | | |
| | | | | (90) | | | | |
| Example | BAPP | — | WPBG-300 | PGMEA/ | S | S | A | S |
| 28 | citraconimide | | (1) | CHN | | | | |
| | (9) | | | (90) | | | | |
| Example | m-BAPP | — | WPBG-300 | PGMEA/ | S | S | A | S |
| 29 | citraconimide | | (1) | CHN | | | | |
| | (9) | | | (90) | | | | |
| Example | BMI | — | WPBG-300 | PGMEA/ | S | S | A | S |
| 30 | citraconimide | | (1) | CHN | | | | |
| | (9) | | | (90) | | | | |
| Example | Monomer- | — | WPBG-300 | PGMEA/ | S | S | S | S |
| 30A | removed BMI | | (1) | CHN | | | | |
| | citraconimide | | | (90) | | | | |
| | (9) | | | | | | | |
| Example | BAN | — | WPBG-300 | PGMEA/CHN | S | S | A | S |
| 31 | citraconimide | | (1) | (90) | | | | |
| | (9) | | | | | | | |
| Example | BMI-80 | BF-BXZ | WPBG-300 | PGMEA/CHN | A | S | S | A |
| 32 | (9) | (2) | (1) | (90) | | | | |
| Example | BMI-80 | NC-3000-L | WPBG-300 | PGMEA/CHN | A | S | S | A |
| 33 | (9) | (2) | (1) | (90) | | | | |
| Example | BMI-80 | DABPA-CN | WPBG-300 | PGMEA/CHN | A | S | S | A |
| 34 | (9) | (2) | (1) | (90) | | | | |
| Example | BMI-80 | BPA-CN | WPBG-300 | PGMEA/CHN | A | S | S | A |
| 35 | (9) | (2) | (1) | (90) | | | | |
| Example | BMI-80 | APG-1 | WPBG-300 | PGMEA/CHN | A | S | S | A |
| 36 | (9) | (2) | (1) | (90) | | | | |
| Example | BMI-80 | APG-2 | WPBG-300 | PGMENCHN | A | S | S | A |
| 37 | (9) | (2) | (1) | (90) | | | | |

Number in brackets represents part by mass of each component

### Example 38

A SiO₂ supporting material with a film thickness of 300 nm was coated with the composition for film formation for lithography in Example 1, and baked at 240° C. for 60 seconds and further at 400° C. for 120 seconds to form an underlayer film with a film thickness of 70 nm. This underlayer film was coated with a resist solution for ArF and baked at 130° C. for 60 seconds to form a photoresist layer with a film thickness of 140 nm. The resist solution for ArF used was prepared by compounding 5 parts by mass of a compound of the following formula (22), 1 part by mass of triphenylsulfonium nonafluoromethanesulfonate, 2 parts by mass of tributylamine, and 92 parts by mass of PGMEA.

Note that the compound of the following formula (22) was prepared as follows. 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula.

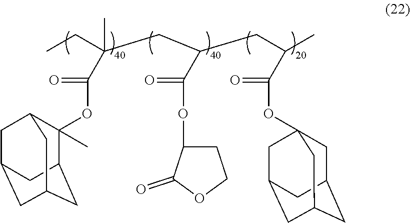

In the above formula (22), 40, 40, and 20 represent the ratio of each constituent unit and do not represent a block copolymer.

Subsequently, the photoresist layer was exposed using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a positive type resist pattern. The evaluation results are shown in Table 3.

### Example 39

A positive type resist pattern was obtained in the same way as Example 38 except that the composition for underlayer film formation for lithography in Example 2 was used instead of the composition for underlayer film formation for lithography in the above Example 1. The evaluation results are shown in Table 3.

### Example 40

A positive type resist pattern was obtained in the same way as Example 38 except that the composition for underlayer film formation for lithography in Example 3 was used instead of the composition for underlayer film formation for lithography in the above Example 1. The evaluation results are shown in Table 3.

### Comparative Example 14

The same operations as in Example 38 were carried out except that no underlayer film was formed so that a photoresist layer was formed directly on a SiO₂ supporting material to obtain a positive type resist pattern. The evaluation results are shown in Table 3.

### [Evaluation]

Concerning each of Examples 38 to 40 and Comparative Example 14, the shapes of the obtained 55 nm L/S (1:1) and 80 nm L/S (1:1) resist patterns were observed under an electron microscope (S-4800) manufactured by Hitachi, Ltd. The shapes of the resist patterns after development were evaluated as goodness when having good rectangularity without pattern collapse, and as poorness if this was not the case. The smallest line width having good rectangularity without pattern collapse as a result of this observation was used as an index for resolution evaluation. The smallest electron beam energy quantity capable of lithographing good pattern shapes was used as an index for sensitivity evaluation.

TABLE 3

| | Composition | | | |
|---|---|---|---|---|
| | for film | | | Resist pattern |
| | formation for | Resolution | Sensitivity | shape after |
| | lithography | (nmL/S) | (μC/cm²) | development |
| Example 38 | As described | 50 | 16 | Good |
| | in Example 1 | | | |
| Example 39 | As described | 60 | 15 | Good |
| | in Example 2 | | | |
| Example 40 | As described | 50 | 15 | Good |
| | in Example 3 | | | |
| Comparative | None | 90 | 42 | Poor |
| Example 14 | | | | |

As is evident from Table 3, Examples 38 to 40 using the composition for film formation for lithography of the present embodiment including a citraconimide or a maleimide were confirmed to be significantly superior in both resolution and sensitivity to Comparative Example 14. Also, the resist pattern shapes after development were confirmed to have good rectangularity without pattern collapse. Furthermore, the difference in the resist pattern shapes after development indicated that the underlayer films of Examples 38 to 40 obtained from the compositions for film formation for lithography of Examples 1 to 3 have good adhesiveness to a resist material.

### (Method for Evaluating Resist Performance of Resist Composition)

Using the above film forming material, a resist composition was prepared according to the formulation shown in Table 4. A clean silicon wafer was spin coated with the homogeneous resist composition, and then prebaked (PB) before exposure in an oven of 110° C. to form a resist film with a thickness of 60 nm. The obtained resist film was irradiated with electron beams of 1:1 line and space setting with an 80 nm interval using an electron beam lithography system (ELS-7500 manufactured by ELIONIX INC.). After irradiation, the resist film was heated at each predetermined temperature for 90 seconds, and immersed in a 2.38 mass % TMAH alkaline developing solution for 60 seconds for development. Subsequently, the resist film was washed with ultrapure water for 30 seconds, and dried to form a negative type resist pattern.

Concerning the formed resist pattern, the line and space were observed under a scanning electron microscope (S-4800 manufactured by Hitachi High-Technologies Corporation) to evaluate the reactivity by electron beam irradiation of the resist composition.

TABLE 4

| | Resist composition | | | |
|---|---|---|---|---|
| | Maleimide | Base | Solvent | Evaluation |
| | Citraconimide | generating | PGME | of resist |
| | [g] | agent [g] | [g] | performance |
| Example 41 | BMI-80 | WPBG-300 | 100.0 | Good |
| | [1.0] | [0.3] | | |
| Example 42 | BAPP | WPBG-300 | 100.0 | Good |
| | citraconimide | [0.3] | | |
| | [1.0] | | | |
| Example 43 | BMI-80 | WPBG-266 | 100.0 | Good |
| | [1.0] | [0.3] | | |
| Example 44 | BAPP | WPBG-266 | 100.0 | Good |
| | citraconimide | [0.3] | | |
| | [1.0] | | | |
| Comparative | BMI-80 | — | — | Poor |
| Example 15 | [1.0] | | | |

As is evident from Table 4, in the resist pattern evaluation, a good resist pattern could be obtained by irradiation with electron beams of 1:1 line and space setting with an 80 nm interval in each of Examples 41 to 44. On the other hand, it was not possible to obtain a good resist pattern in Comparative Example 15, which contained no latent base generating agent.

The film forming material for lithography of the present embodiment is applicable to a wet process, and is useful for forming a photoresist underlayer film that is not only excellent in heat resistance and film flatness in a supporting material having difference in level, but also has solubility in a solvent, long term storage stability in a solution form, and curability at low temperature.

Therefore, the composition for film formation for lithography comprising the film forming material for lithography can be utilized widely and effectively in various applications that require such performances. In particular, the present invention can be utilized particularly effectively in the field of underlayer films for lithography and underlayer films for multilayer resist.

1. A film forming material for lithography comprising:
a compound having a group of formula (0A): 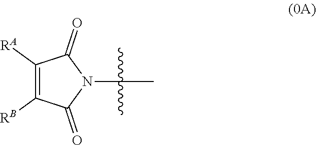
wherein
R^{A} and R^{B} are each independently a hydrogen atom or an alkyl group having 1 to 4 carbon atoms; and
a latent curing accelerator.

2. The film forming material for lithography according to claim 1, wherein the decomposition temperature of the latent curing accelerator is 600° C. or lower.

3. The film forming material for lithography according to claim 1, wherein the latent curing accelerator is a latent base generating agent.

4. The film forming material for lithography according to claim 1, wherein the compound having a group of formula (0A) has two or more groups of formula (0A).

5. The film forming material for lithography according to claim 1, wherein the compound having a group of formula (0A) is a compound having two groups of formula (0A) or an addition polymerization resin of a compound having a group of formula (0A).

6. The film forming material for lithography according to claim 1, wherein the compound having a group of formula (0A) is represented by formula (1A₀): 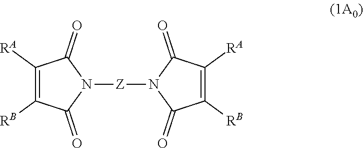
wherein
R^{A} and R^{B} are as defined above; and
Z is a divalent hydrocarbon group having 1 to 100 carbon atoms and optionally containing a heteroatom.

7. The film forming material for lithography according to claim 1, wherein the compound having a group of formula (0A) is represented by formula (1A): 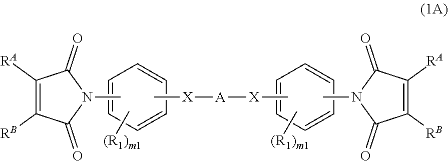
wherein
R^{A} and R^{B} are as defined above;
each X is independently a single bond, —O—, —CH₂—, —C(CH₃)₂—, —CO—, —C(CF₃)₂—, —CONH—, or —COO—;
A is a single bond, an oxygen atom, or a divalent hydrocarbon group having 1 to 80 carbon atoms and optionally containing a heteroatom;
each R₁ is independently a group having 0 to 30 carbon atoms and optionally containing a heteroatom; and
each m1 is independently an integer of 0 to 4.

8. The film forming material for lithography according to claim 7, wherein:
A is a single bond, an oxygen atom, —(CH₂)ₚ—, —CH₂C(CH₃)₂CH₂—, —(C(CH₃)₂)ₚ—, —(O(CH₂)_{q})ₚ—, —(O(C₆H₄))ₚ—, or any of the following structures: 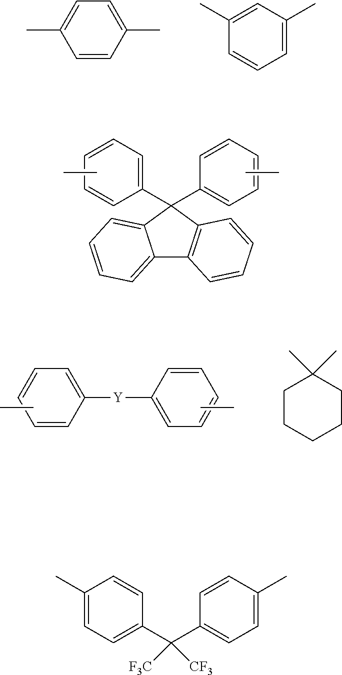
Y is a single bond, —O—, —CH₂—, —C(CH₃)₂—, —C(CF₃)₂—, 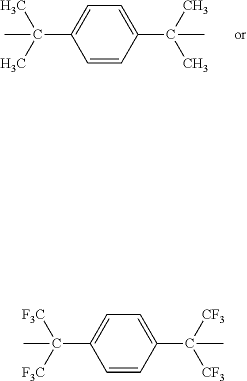
p is an integer of 0 to 20; and
q is an integer of 0 to 4.

9. The film forming material for lithography according to claim 1, wherein the compound having a group of formula (0A) is represented by formula (2A): 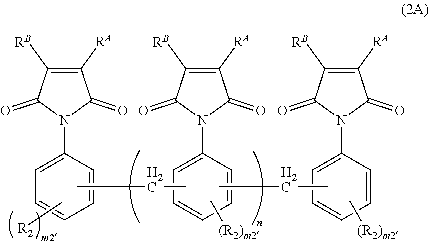
wherein
R^{A} and R^{B} are as defined above;
each R₂ is independently a group having 0 to 10 carbon atoms and optionally containing a heteroatom;
each m2 is independently an integer of 0 to 3;
each m2′ is independently an integer of 0 to 4; and
n is an integer of 0 to 4.

10. The film forming material for lithography according to claim 1, wherein the compound having a group of formula (0A) is represented by formula (3A): 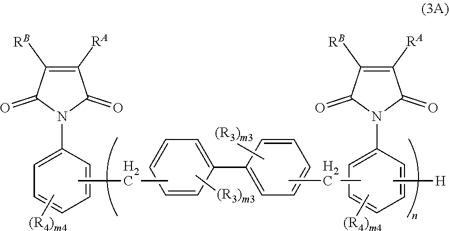
wherein
R^{A} and R^{B} are as defined above;
R₃ and R₄ are each independently a group having 0 to 10 carbon atoms and optionally containing a heteroatom;
each m3 is independently an integer of 0 to 4;
each m4 is independently an integer of 0 to 4; and
n is an integer of 1 to 4.

11. The film forming material for lithography according to claim 1, wherein a content ratio of the latent curing accelerator is 1 to 25 parts by mass based on 100 parts by mass of a total mass of the compound having a group of formula (0A).

12. The film forming material for lithography according to claim 1, further comprising a crosslinking agent.

13. The film forming material for lithography according to claim 12, wherein the crosslinking agent is at least one selected from the group consisting of a phenol compound, an epoxy compound, a cyanate compound, an amino compound, a benzoxazine compound, a melamine compound, a guanamine compound, a glycoluril compound, a urea compound, an isocyanate compound, and an azide compound.

14. The film forming material for lithography according to claim 12, wherein the crosslinking agent has at least one allyl group.

15. The film forming material for lithography according to claim 12, wherein a content ratio of the crosslinking agent is 0.1 to 100 parts by mass based on 100 parts by mass of a total mass of the compound having a group of formula (0A).

16. A composition for film formation for lithography comprising the film forming material for lithography according to claim 1 and a solvent.

17. The composition for film formation for lithography according to claim 16, wherein the film for lithography is an underlayer film for lithography.

18. An underlayer film for lithography formed by using the composition for film formation for lithography according to claim 17.

19. The composition for film formation for lithography according to claim 16, wherein the film for lithography is a resist film.

20. A resist film formed by using the composition for film formation for lithography according to claim 19.

21. A method for forming a resist pattern, comprising:
a resist film forming step of forming a resist film on a supporting material by using the composition for film formation for lithography according to claim 19; and
a development step of irradiating a predetermined region of the resist film formed by the resist film forming step with radiation for development.

22. The method for forming a resist pattern according to claim 21, wherein the method is a method for forming an insulating film pattern.

23. A method for forming a resist pattern, comprising the steps of:
forming an underlayer film on a supporting material by using the composition for film formation for lithography according to claim 17;
forming at least one photoresist layer on the underlayer film; and
irradiating a predetermined region of the photoresist layer with radiation for development.

24. A method for forming a circuit pattern, comprising the steps of:
forming an underlayer film on a supporting material by using the composition for film formation for lithography according to claim 17;
forming an intermediate layer film on the underlayer film by using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask;
etching the underlayer film with the obtained intermediate layer film pattern as an etching mask; and
etching the supporting material with the obtained underlayer film pattern as an etching mask, thereby forming a pattern on the supporting material.
